(19) United States
(12) Patent Application Publication
(10) Pub. No.: US 2025/0112163 A1
(43) Pub. Date: Apr. 3, 2025

(54) THROUGH-GLASS VIA LINERS FOR INTEGRATED CIRCUIT DEVICE PACKAGES

(71) Applicant: Intel Corporation, Santa Clara, CA (US)

(72) Inventors: Pratyush Mishra, Tempe, AZ (US); Pratyasha Mohapatra, Hillsboro, OR (US); Srinivas Pietambaram, Chandler, AZ (US); Whitney Bryks, Tempe, AZ (US); Mahdi Mohammadighaleni, Phoenix, AZ (US); Joshua Stacey, Chandler, AZ (US); Travis Palmer, San Diego, CA (US); Yosef Kornbluth, Phoenix, AZ (US); Kuang Liu, Quen Creek, AZ (US); Astitva Tripathi, Mesa, AZ (US); Yuqin Li, Chandler, AZ (US); Rengarajan Shanmugam, Tempe, AZ (US); Xing Sun, Chandler, AZ (US); Brian Balch, Chandler, AZ (US); Darko Grujicic, Chandler, AZ (US); Jieying Kong, Chandler, AZ (US); Nicholas Haehn, Scottsdale, AZ (US); Jacob Vehonsky, Chandler, AZ (US); Mitchell Page, Mesa, AZ (US); Vincent Obiozo Eze, Chandler, AZ (US); Daniel Wandera, Chandler, AZ (US); Sameer Paital, Mesa, AZ (US); Gang Duan, Chandler, AZ (US)

(73) Assignee: Intel Corporation, Santa Clara, CA (US)

(21) Appl. No.: 18/375,203

(22) Filed: Sep. 29, 2023

(51) Int. Cl. H01L 23/538; H01L 21/48; H01L 23/15; H01L 25/065

(52) U.S. Cl. CPC H01L 23/5384; H01L 21/4857; H01L 21/486; H01L 23/15; H01L 23/5383; H01L 25/0655

(57) ABSTRACT

An IC die package includes a substrate comprising glass and a plurality of holes extending through the glass. A via metallization is present within the holes. A liner is between the via metallization and the glass. The liner can comprise a beta-titanium alloy layer, polymer hydrogel layer and an MXene seed layer, an organic material layer and a metal layer, or an organic material layer between first and second metal layers. A polymer layer may be formed by electrodeposition of charged nanoparticles.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package can also communicatively connect the IC chip to other packaged IC chips and/or a scaled host component, such as a package substrate, or a printed circuit board. Multiple IC chips can be co-assembled, for example, into a multi-die package (MCP).

Some multi-die package architectures may include IC die attached to a glass substrate. In these multi-die packages, the IC die are coupled to electrically conductive through-glass vias (TGVs) extending through the glass substrate. TGV reliability is important for IC device reliability.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIG. 1A illustrates a flow diagram of methods for forming an integrated circuit (IC) device package structure including IC die coupled to a glass preform comprising through-glass vias (TGVs) with liners between glass and via metallization, the methods of FIG. 1A including alternative liner materials and liner deposition operations, in accordance with some embodiments;

FIGS. 1B-1F illustrate flow diagrams of alternative liner materials and operations for depositing a liner within a TGV of the methods of FIG. 1A, in accordance with some embodiments;

FIGS. 2A, 2B, and 2C illustrate cross-sectional views of an IC device package structure evolving to include TGVs with liners between the glass and via metallization as selected operations in the methods illustrated in FIG. 1A are performed, in accordance with some embodiments;

FIGS. 3A and 3B illustrate cross-sectional views of a portion of a glass preform evolving to include a liner within a through hole as selected operations in the methods illustrated in FIG. 1B are performed, and FIG. 3C is a graph of elastic modulus data for materials that may be included in the liner of FIGS. 3A and 3B, in accordance with some embodiments;

FIGS. 4A and 4B illustrate cross-sectional views of a portion of a glass preform evolving to include a liner within a through hole as selected operations in the methods illustrated in FIG. 1C are performed, in accordance with some embodiments;

FIGS. 5A to 5D illustrate cross-sectional views of a portion of a glass preform evolving to include a liner within a through hole as selected operations in the methods illustrated in FIG. 1D are performed, in accordance with some embodiments;

FIGS. 6A to 6D illustrate cross-sectional views of a portion of a glass preform evolving to include a liner within a through hole as selected operations in the methods illustrated in FIG. 1E are performed, in accordance with some embodiments;

FIGS. 7A to 7D illustrate cross-sectional views of a portion of a glass preform evolving to include a liner within a through hole as selected operations in the methods illustrated in FIG. 1F are performed, in accordance with some embodiments;

FIGS. 8A and 8B illustrate cross-sectional views of an IC device package structure evolving to include TGVs with liners between glass and via metallization as selected operations in the methods illustrated in FIG. 1A are performed, in accordance with some embodiments;

FIGS. 9A, 9B and 9C illustrate cross-sectional views of an IC device package structure evolving to include multiple IC dies interconnected by an electrical routing structure built up on a side of a glass that includes TGVs with liners between glass and via metallization as selected operations in the methods illustrated in FIG. 1A are performed, in accordance with some embodiments;

FIG. 10 illustrates a system including the IC device package structure illustrated in FIG. 9C attached to a host component with solder features, in accordance with some embodiments;

FIG. 11 illustrates a mobile computing platform and a data server machine employing IC device package structures comprising glass substrates with TGVs with liners between glass and via metallization, in accordance with some embodiments; and

FIG. 12 is a functional block diagram of an electronic computing device employing IC device package structures comprising glass substrates with TGVs with liners between glass and via metallization, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Some multi-die package architectures may include IC die attached to a glass substrate. In these multi-die packages, the IC die are coupled to electrically conductive through-glass vias (TGVs) extending through the glass substrate. TGV reliability is important for IC device reliability. However, a glass substrate has a significantly lower coefficient of thermal expansion (CTE) than a conventional organic substrate. In contrast to conventional organic substrates, there is a large CTE mismatch between the glass substrate and the metal in the TGV. Via metallization, e.g., copper, may have an elastic modulus of at least 125 GPa, while glass may have an elastic modulus of about 75 GPa. Manufacturing typically includes heating and cooling cycles, during which internal stress can develop in a glass substrate with TGVs. As a result of the internal stress, less stress is required to cause failure of the glass substrate with TGVs as compared with conventional organic substrates with copper-filled vias. With glass substrates, mechanical failures may occur during reliability testing. Device reliability and package yields for glass substrates with TGVs may be less than with conventional organic copper-cored/coreless substrates with copper-filled TGVs.

Integrated circuit (IC) device package structures that include a glass substrate (or other layer) with conductive through-glass vias (TGVs) are described herein. In exemplary embodiments, the TGVs include a liner between the glass and via metallization within the TGVs. As noted, glass and via metallization (e.g., predominantly copper) have mismatched coefficients of thermal expansion (CTE). Semiconductor device fabrication typically includes multiple heating and cooling cycles. Liners comprised of a variety of material and layers are described herein. Each of the various liners may reduce internal stress within the glass resulting from divergent rates of expansion and contraction of glass and via metallization during thermal cycles. In some examples a liner has a high resistivity and a seed layer may be deposited on the liner to facilitate electrodeposition of a metal. In addition, a seed layer that may that may have a better adherence property than some known seed layers is described. Further, electrodeposition processes for forming a polymer liner are disclosed.

In some embodiments, the liner comprises a beta-titanium alloy, which may accommodate stress that develops between the glass and via metallization. The beta-titanium alloy liner may have an elastic (Young's) modulus as low as 25 GPa. While a liner could be formed from metal other than a beta-titanium alloy, other metals may have an elastic modulus of 40 GPa or more. Because the modulus of the beta-titanium alloy liner may be lower than that of some other metals, one advantage of a disclosed liner is that it may be made thinner than liners made from those other metals, which enables TGVs to be formed with a higher aspect ratio.

In some embodiments, the liner comprises a layer of polymer hydrogel on the glass and an MXene seed layer on the polymer hydrogel. The polymer hydrogel may accommodate stress that develops between the glass and via metallization. Electrodeposition of metal within a via requires a seed layer of conductive material on the surface of the polymer hydrogel. A Ti/Cu seed layer might be used. However, adherence of the Ti/Cu seed layer to the polymer hydrogel may be poor. In contrast, an MXene seed layer may adhere better to the polymer hydrogel liner and provide good conductivity. In an embodiment, the MXene seed layer comprises Ti₃C₂Tₓ, wherein Tₓ is a functional group, such as —OH, —F, or —O.

In some embodiments, the liner comprises a polymer layer formed using an electrodeposition process, which may accommodate internal stress that develops between the glass and via metallization. A polymer layer could be formed using a chemical vapor deposition (CVD) process. However, CVD-deposited polymer films are expensive to grow into meaningfully thick layers. Electrodeposition requires that polymer molecules comprise an electric charge and that the glass have a conductive surface. In some embodiments, a conductive seed layer is deposited on the glass. Glass with a conductive seed layer on a surface serves as an electrode, e.g., a cathode. In embodiments, the polymer comprises charged nanoparticles. In some embodiments, the seed layer is biased, and the glass is immersed in solution a containing charged polymer nanoparticles. In another embodiment, a charged hard mask is positioned over the glass and the glass is exposed to an aerosol containing charged polymer nanoparticles. Subsequently, the glass may be annealed or allowed to cure so that the polymer nanoparticles meld into a continuous film.

In some embodiments, the liner comprises two layers: an organic material layer and a metal layer. Individually, the organic material layer and the metal layer each reduce stress that develops between the glass and via metallization. Advantageously, when the liner includes both an organic material layer and a metal layer, internal stress between the glass and via metallization may be reduced by an amount that is greater than the stress reduction provided by either layer individually. The metal layer may include a metal with a low elastic modulus, such as aluminum (Al) or tin (Sn). The organic material layer may include an organic material with a low elastic modulus, such as an epoxy-based dielectric, with or without inorganic filler, a polyimide, or a parylene variant. The organic material layer may be deposited on the glass with the metal layer deposited over the organic material layer. Alternatively, the metal layer may be deposited on the glass with the organic material layer deposited over the metal layer.

In some embodiments, the liner comprises three layers: a first metal layer, a second metal layer, and an organic material layer between the first and second metal layers. One issue that may arise with an organic liner is cohesive failure due to the stiff contraction of the via metallization. The second metal layer that separates the organic material layer from the via metallization may prevent the organic material layer from being pulled apart from the via metallization. The second metal layer may have an elastic modulus that is greater than the elastic modulus of the organic material layer.

An electrical routing structure comprising redistribution layer (RDL) metallization may be built-up on at least one side of the glass, and IC die(s) assembled to the routing structure. The liner within the TGVs may be absent from metal features of the routing structure.

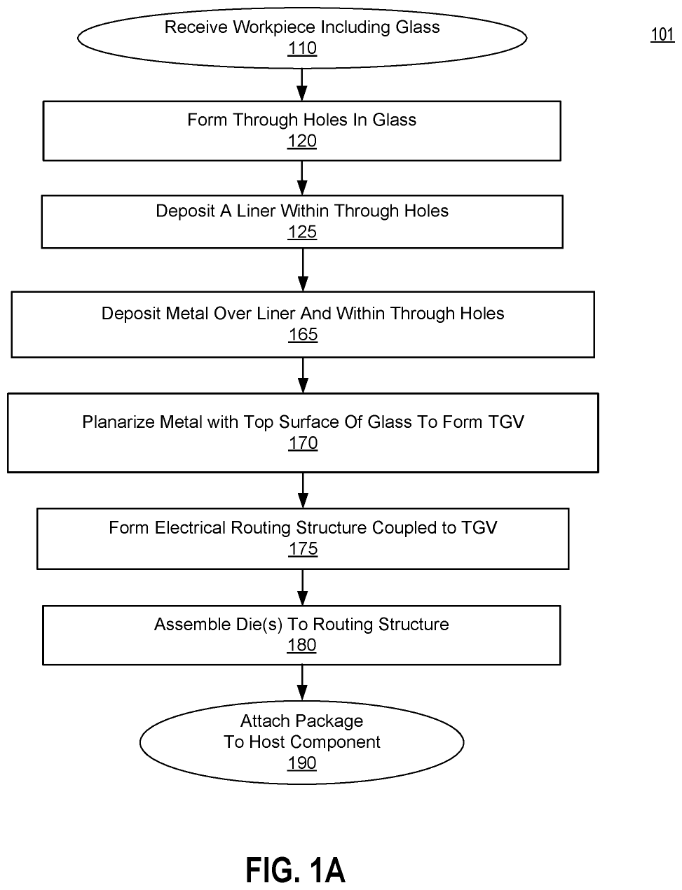

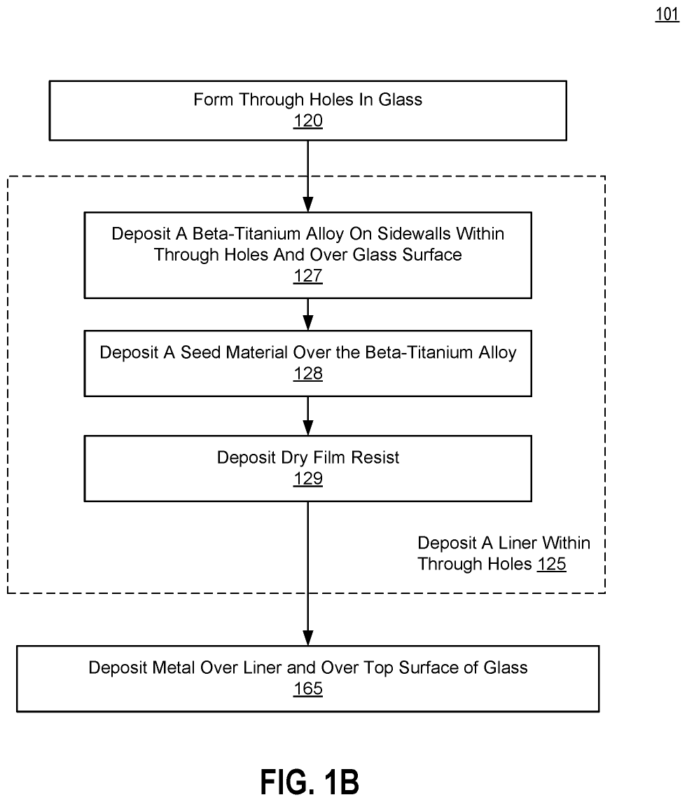

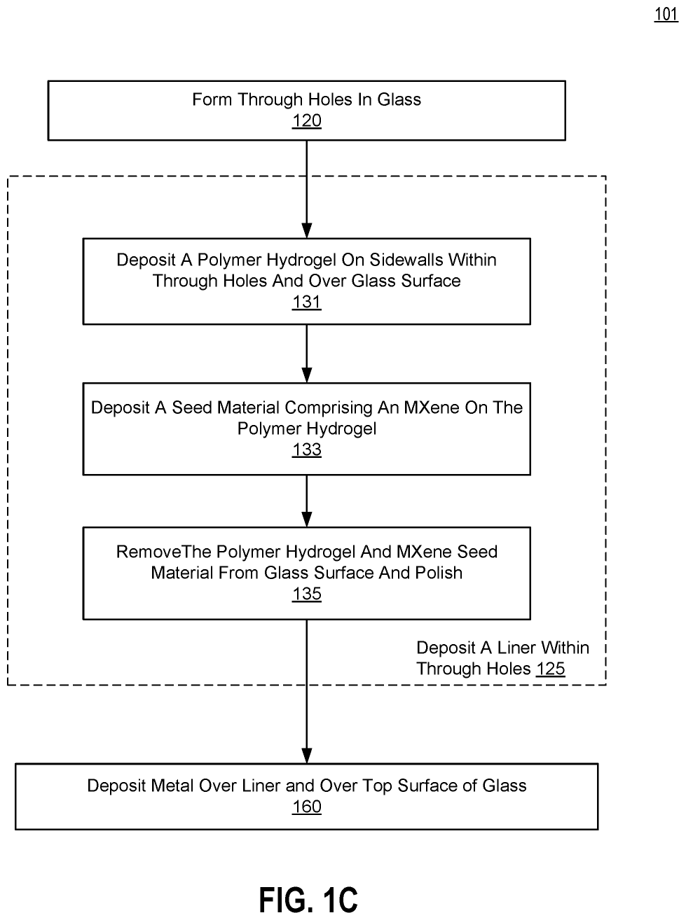

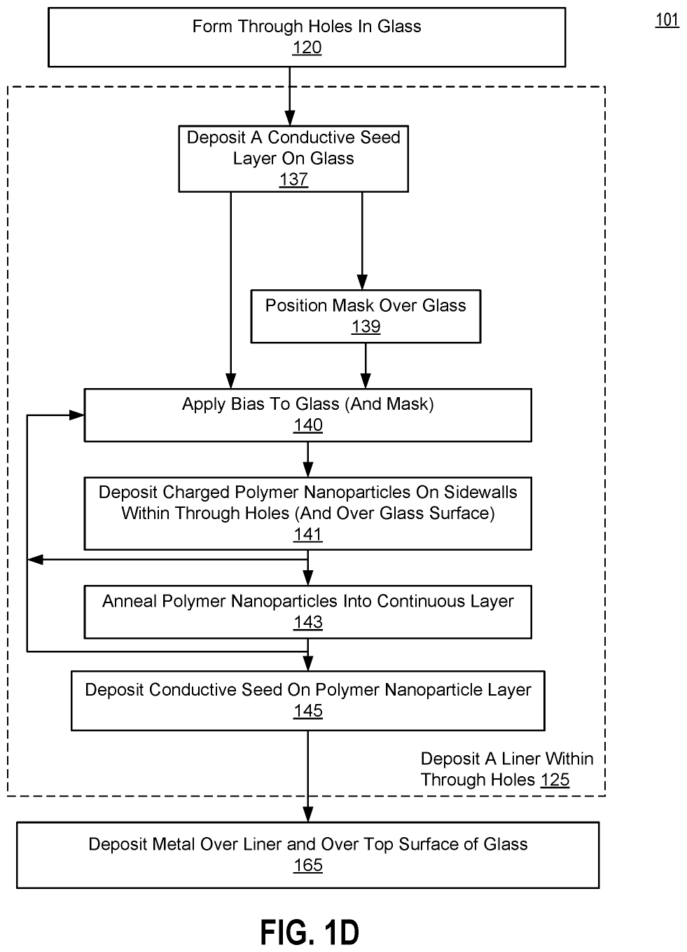

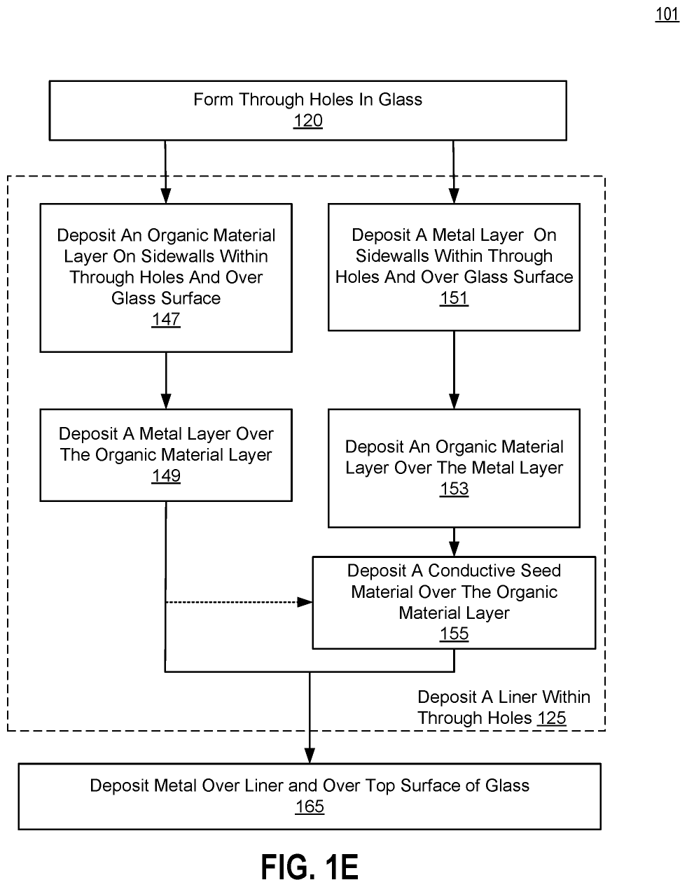

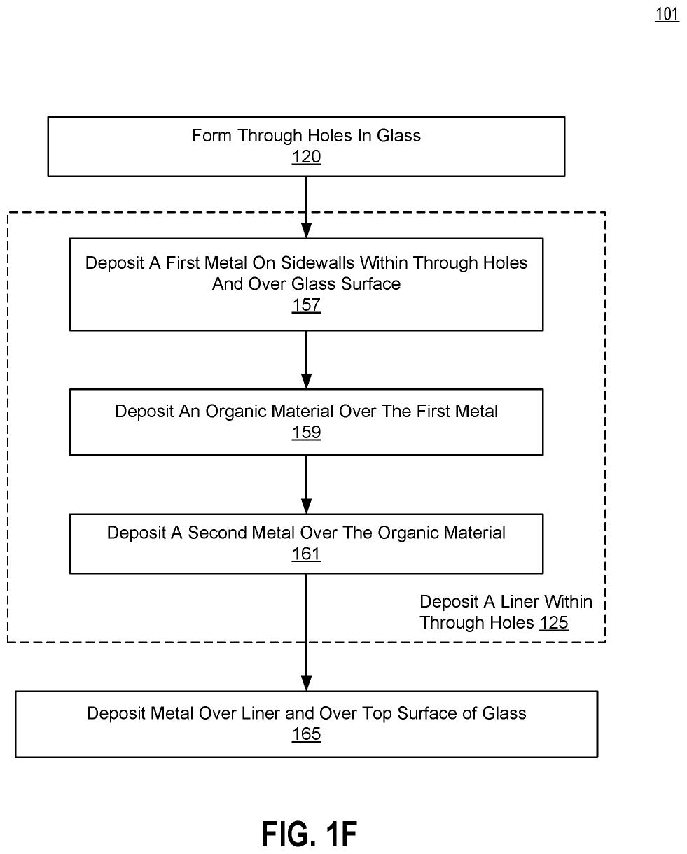

As illustrated in FIGS. 1A-1F, a variety of fabrication methods may be practiced to form IC device package structures having one or more of the features described herein. FIG. 1A illustrates a flow diagram of methods 101 for forming an IC device package structure including IC die coupled to a bulk glass layer comprising through-glass vias (TGVs) having a liner, in accordance with some embodiments. Methods 101 begin at input 110 where a workpiece including a thickness of glass is received. The workpiece may be prepared upstream of methods 101 and may be in a large panel format, a wafer format, or the like. In addition to the glass, the workpiece received at input 110 may comprise one or more materials upon which electrical routing structures may be formed.

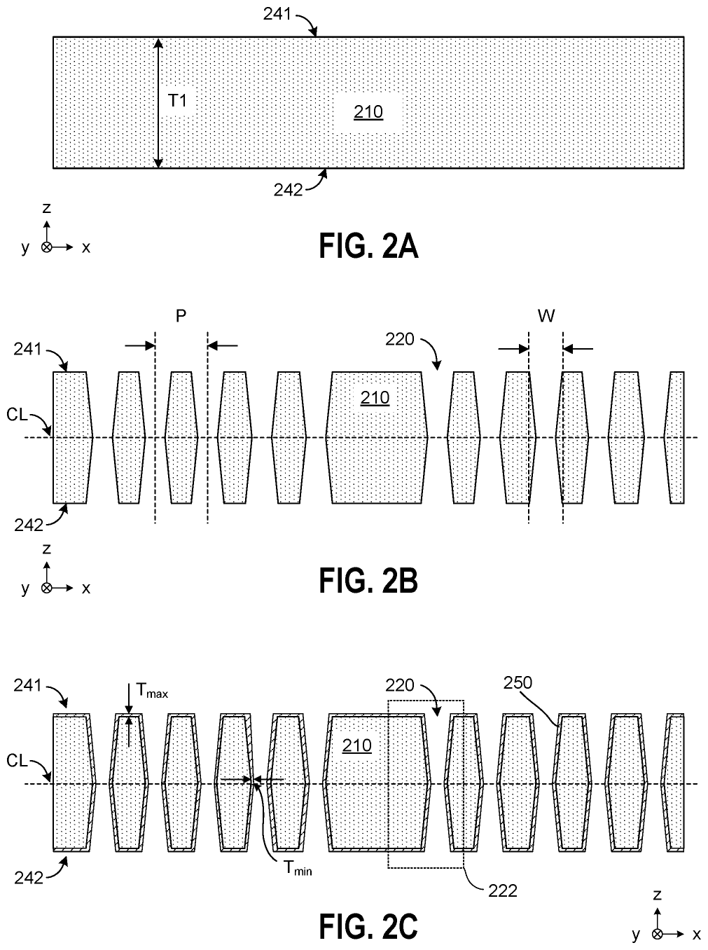

FIG. 2A is a cross-sectional view of an exemplary workpiece including glass 210. Advantages of fabricating IC device package structures upon such a glass are that the flatness and/or thickness control for a preform of glass is superior to that of starting substrates based on organic materials (e.g., epoxy), and the costs can be significantly lower than for monocrystalline materials (e.g., silicon). Glass 210 is a solid bulk material layer that may have been previously formed into any shape in plan view (e.g., x-y plane) suitable for a packaging workpiece, such as rectangular. Glass 210 has a thickness T1 that may vary with implementation, for example to limit warpage while remaining thin enough to permit the formation of through vias at a pitch as small as is enabled by the surface flatness of glass 210. In exemplary embodiments, thickness T1 is advantageously 200 μm to 2000 μm.

Glass 210 is advantageously predominantly silicon and oxygen. In some embodiments, glass 210 comprises at least 23 percent silicon and at least 26 percent oxygen, by weight (i.e., wt. %). Glass 210 may further include one or more additives, such as, Aluminum, Boron, Magnesium, Calcium, Barium, Tin, Sodium, Potassium, Strontium, Phosphorus, Zirconium, Lithium, Titanium, or Zinc. In some embodiments where glass 210 comprises at least 23 wt. % Si and at least 26 wt. % O, glass 210 further comprises at least 5 wt. % Al. Additives within glass 210 may form suboxides (A2O) monoxides (AO), binary oxides (AO2), ternary oxides (ABO3), and mixtures thereof. For example, glass 210 may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li2O), TiOx (e.g., TiO2), or ZnOx (e.g., ZnO2). Depending on chemical composition, glass 210 may therefore be referred to as silica, fused silica, aluminosilicate, borosilicate, or alumino-borosilicate, for example.

Glass 210 is advantageously a bulk material of substantially homogeneous composition in contrast to a composite material that may merely comprise glass fillers and/or fibers. Although glass 210 is substantially amorphous in some embodiments, glass 210 may also have other morphology or microstructure, such as polycrystalline (e.g., nanocrystalline).

Although not depicted, one or more material layers may clad either or both of the front-side surface 241 or back-side surface 242 of glass 210 so that glass 210 is a bulk or core layer of a multi-layered substrate. Exemplary cladding materials include inorganic materials such as silicon nitride (SiNx) or silicon oxynitride (SiOxNy). In other embodiments, a silicon layer (polycrystalline or monocrystalline) may clad one or both sides of glass 210. Organic material layers, such as polymer dielectric materials, may also clad one or more sides of glass 210. Hence, while glass 210 is advantageously substantially free of organic materials (e.g., no adhesives, etc.), a workpiece may include organic material within a substrate stack that includes glass 210.

In some embodiments, surfaces of glass 210 comprises a layer of indium tin oxide (ITO) on its surfaces. ITO coated glass panels are electrically conductive.

Returning to FIG. 1A, methods 101 continue at block 120 where features (e.g., through holes) are formed in the glass. The features may be fabricated with any process known to be suitable for bulk glass. In some embodiments, block 120 entails laser ablation, a glass etch process (laser-assisted, or otherwise), or any other technique known to be suitable for forming features (e.g., holes) through a thickness of the workpiece received at input 110 at a desired diameter and feature pitch.

FIG. 2B illustrates an exemplary embodiment indicative of a substantially symmetrical two-sided hole formation process resulting in through holes 220 that are substantially symmetric about a longitudinal z-axis (demarked in dashed line) but with a tapered (e.g., x dimension) lateral width W that is largest at each of a front-side surface 241 and a back-side surface 242 of glass 210. Through holes 220 have a smallest lateral width W proximal to one-half of thickness T1 or a centerline plane CL of glass 210. The largest width W may vary with implementation. However, in some examples the largest width W is 100 μm, or less, and advantageously 50 μm, or less. Accordingly, the aspect ratio (T1: largest width W) of through holes 220 may also vary with an exemplary range being 4-20. In some embodiments where glass 210 has a thickness T1 of at least 500 μm, through holes 220 have a minimum lateral pitch P that is 200 μm, or less, and advantageously 100 μm, or less. Although the symmetrical taper illustrated in FIG. 2B is indicative of a two-sided through-hole formation process, single-sided asymmetrical though hole embodiments are also possible. Also, although only through holes are illustrated in FIG. 2B, blind holes or recesses that do not pass entirely through thickness T1 may also be fabricated into one or more of front-side surface 241 or back-side surface 242. Through holes 220 may have any shape within a plan view (x-y) plane, such as substantially circular, rectangular, or any other polygon. The plan view shape may vary over thickness T1.

Returning to FIG. 1A, methods 101 continue at block 125 where a liner is deposited upon sidewalls of the features formed into a bulk glass. FIG. 2C illustrates an exemplary liner 250 that has been deposited upon surfaces of glass 210. Portion 222 of glass 210 includes a representative through hole 220. FIGS. 1B-1F illustrate alternative materials and alternative fabrication methods for depositing liner 250 corresponding with block 125. Each of the alternative fabrication methods employ a sufficiently compliant material or materials (i.e., of sufficiently low elastic modulus) to accommodate internal stress between the glass and metallization subsequently deposited in the features. The magnitude of stress developed may vary with implementation, for example as a function of feature geometry and thermal stress. Thicknesses of liner 250 may vary with implementation. The liner materials, the diameter and depth of the opening, along with the space required for via metallization are among the factors that will determine liner thickness.

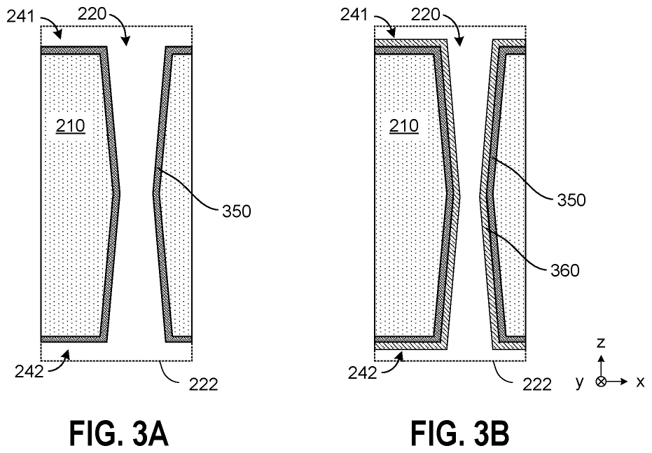

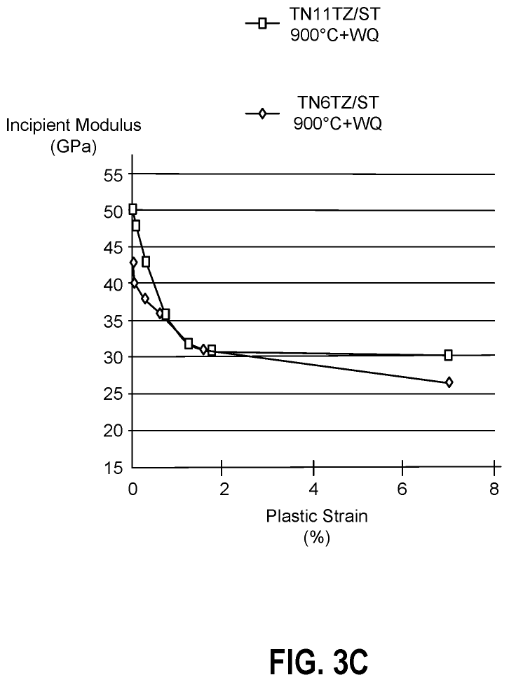

FIG. 1B illustrates methods for depositing a liner upon sidewalls of the features formed into a bulk glass according to some embodiments. A liner (or layer) comprising a beta-titanium alloy having a low elastic modulus is deposited upon a sidewall of the holes, and over a surface of the glass between the through holes at block 127. The low modulus beta-titanium alloy liner is preferably formed by physical vapor deposition (PVD). In some embodiments, the low modulus beta-titanium alloy liner may be formed by chemical vapor deposition (CVD) or atomic layer deposition (ALD)). Some operations of the methods of FIG. 1B are illustrated using representative portion 222 in FIGS. 3A and 3B.

FIG. 3A illustrates an example of a low modulus beta-titanium alloy liner (or layer) 350 that has been deposited upon surfaces of glass 210. Layer 350 may include titanium (Ti), niobium (Nb), tantalum (Ta), and zirconium (Zr). In embodiments, the liner 350 is comprised of beta-titanium alloy with an elastic modulus in the range of about 25 to 55 gigapascals (GPa). In embodiments, the liner 350 is comprised of beta-titanium alloy with an elastic modulus in the range of about 25 to 40 GPa, or an elastic modulus less than or equal to about 40 GPa. In other embodiments, the liner 350 is comprised of beta-titanium alloy with an elastic modulus in the range of about 25 to 35 GPa, or an elastic modulus less than or equal to about 35 GPa. In still other embodiments, the liner 350 is comprised of beta-titanium alloy with an elastic modulus in the range of about 25 to 30 GPa, or an elastic modulus less than or equal to about 30 GPa.

FIG. 3C depicts elastic modulus data for two species of beta-titanium alloy: Ti-29Nb-11Ta-5Zr (TN11TZ in the figure) and Ti-29Nb-6Ta-5Zr (TN6TZ in the figure). In embodiments, liner 350 is comprised of Ti-29Nb-11Ta-5Zr or Ti-29Nb-6Ta-5Zr. Other examples of beta-titanium alloy that may be included in liner 350 include: Ti-33Nb-4Sn (elastic modulus up to 36 GPa), Ti-35Nb-4Sn (elastic modulus up to 40 GPa), Ti-33.6Nb-4Sn (elastic modulus up to 52 GPa), Ti-35.3Nb-5.1Ta-7.1Zr (elastic modulus up to 55 GPa), and Ti-29Nb-13Ta-7.1Zr (elastic modulus up to 55 GPa).

It should be appreciated that liner 350 may comprise any species of beta-titanium alloy with a suitable elastic modulus, e.g., within the ranges or limits specified herein. The low elastic moduli of various species of beta-titanium alloy allows liner 350 to be made thinner than would otherwise be required, which is an advantage. Liners comprised of beta-titanium alloy also mitigate detachment issues that sometimes arise with low tensile strength organic liners, which is also an advantage.

The thickness of liner 350 will vary depending on the implementation. The diameter and depth of the opening, along with the space required for metallization are among the factors that will determine liner thickness. In some examples, the thickness of liner 350 may be similar to liners comprised of parylene or aluminum. In some examples, liner 350 has a maximum thickness of less than 10 nm. In other examples, liner 350 has a maximum thickness of less than 100 nm, 200 nm, or 300 nm. In still other examples, liner 350 has a maximum thickness of 1 μm, or 4 μm.

Referring again to FIG. 1B, a seed layer may be deposited over low modulus beta-titanium alloy liner 350 at block 128. FIG. 3B illustrates an example of a seed layer 360 deposited over liner 350. The seed layer 360 may be deposited by an electroless method, such as PVD, CVD, or ALD. Seed layer 360 may be any suitable conductive material, such as copper, or a mixture of copper and titanium. It should be appreciated, however, that seed layer 360 is optional. Electrodeposition of copper or other metal in a through hole requires an electrically conductive liner. Because a beta-titanium alloy is conductive, deposition of a seed layer may be omitted.

Referring again to FIG. 1B, a dry film resist may be deposited over low modulus beta-titanium alloy present on surfaces 241 and 242 at block 129. If a seed layer is deposited over liner 350, the dry film resist may be deposited over portions of the seed layer present on surfaces 241 and 242. (A dry film resist is not deposited (omitted from) within the through holes 220.) Beta-titanium alloy on sidewalls of the through holes 220 and seed layer 360, if any, on sidewalls of the through holes 220 does not receive the dry film resist. For example, the dry film resist is only deposited over a surface of the glass and between the through holes at block 129. After copper is electrochemically deposited (at block 165), the resist layer is removed, and beta-titanium alloy, and seed layer metal, if any, present on surfaces 241 and 242 is etched away.

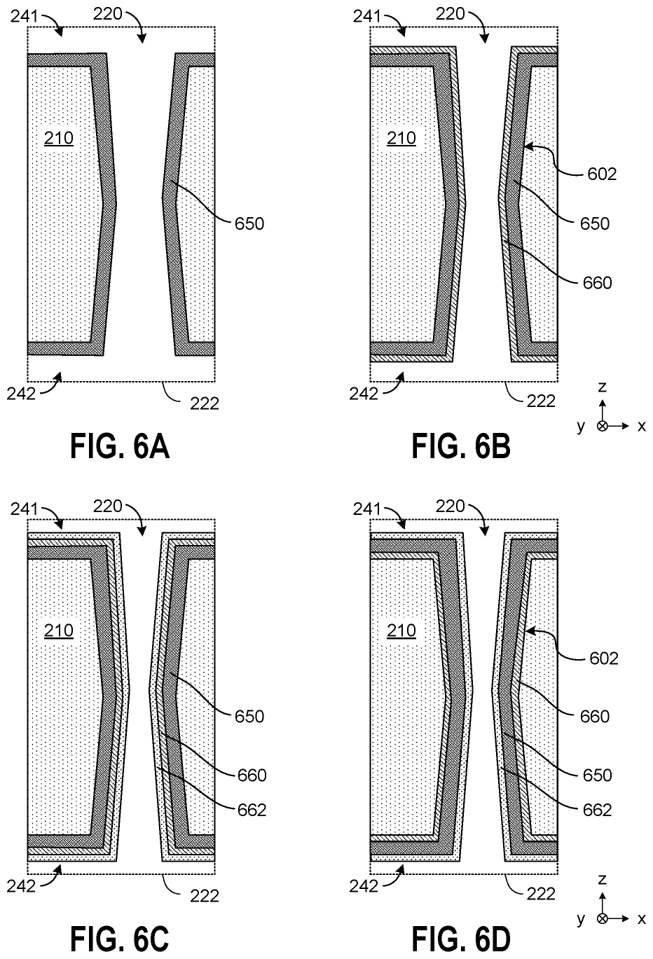

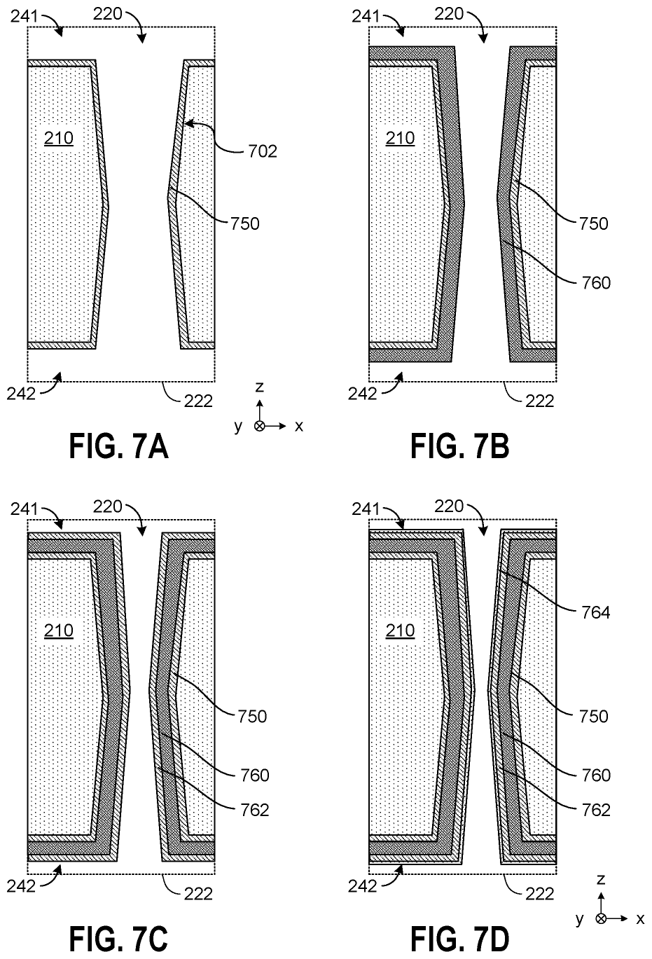

In some embodiments, low modulus beta-titanium alloy liner 350 may be one layer in a liner comprised of a plurality of material layers. For example, a though-glass via liner may comprise an organic layer and a metal layer (e.g., see FIG. 6C, 6D), and the metal layer may be the low modulus beta-titanium alloy described herein as liner 350. As another example, a though-glass via liner may comprise a first metal layer, a second metal layer, and an organic layer between the first and second metal layers (e.g., see FIG. 7C). Either or both of the first and second metal layers may be the low modulus beta-titanium alloy described herein as liner 350.

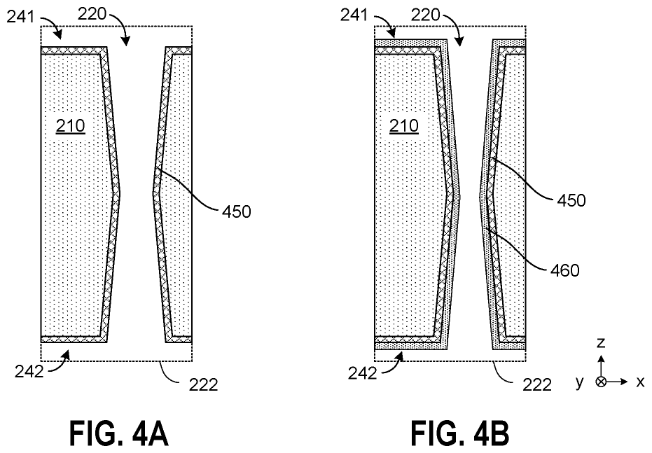

FIG. 1C illustrates methods for depositing a liner upon sidewalls of the features formed into a bulk glass according to some embodiments. A liner comprising a polymer hydrogel having a low elastic modulus is deposited upon a sidewall of the holes, and over a surface of the glass between the through holes at block 131. In various embodiments, the polymer hydrogel liner may be formed by inkjet coating, slit coating, spin coating, spray coating, or doctor blade coating. Some operations of the methods of FIG. 1C are illustrated using representative portion 222 in FIGS. 4A and 4B.

FIG. 4A illustrates an example of a polymer hydrogel liner 450 that has been deposited upon surfaces of glass 210. In various embodiments, the polymer hydrogel liner 450 is a mixture of a solvent (e.g., dimethyl sulfoxide (DMSO), dimethylformamide (DMF), N-Methyl-2-pyrrolidone (NMP), Gamma-butyrolactone (GBL), Toluene, etc.), H₂O, organic polymers (e.g., poly(3,4-ethylenedioxythiophene) polystyrene sulfonate (PEDOT: PSS), polyvinyl alcohol, polyaniline, polyacrylamide, cellulose, chitosan, poly(acrylic acid). Polymer hydrogel liner 450 may include additives and binders. In an embodiment, the polymer hydrogel comprises a solvent, H₂O, and an organic polymer. Polymer hydrogel possesses good mechanical properties. The polymer hydrogel may have a tensile elongation of about 1000%, stable temperature tolerance, good adherence to various substrates, and a rapid self-healing capability.

Referring again to FIG. 1C, an MXene seed layer may be deposited over polymer hydrogel liner 450 at block 133. FIG. 4B illustrates an example of MXene seed layer 460 deposited over liner 450. The seed layer 460 may be deposited by PVD, CVD, ALD, or other coating methods. Seed layer 460 comprises an MXene. MXene may be a transition metal carbide, transition metal nitride, transition metal carbonitride, or the like. The MXene material may be a compound (MX) of a transition metal (M: Ti, V, Cr, Ta, Nb, or the like) and carbon or nitrogen (X: C or N). In various embodiments, the MXene material has the molecular formular Mₙ₊₁XₙTₓ (n=1-3), where M is a transition metal, X is a carbon or nitrogen, and T is a functional group (e.g., —OH, —O, —F) on the surface of substance, n and x are the number atoms and functional groups, respectively. MXene material has a nano-scale multilayer thin film structure, e.g., 3 to 7 atomic layers. MXene material has a two-dimensional (2D) crystal structure. In embodiments, the MXene seed layer 460 comprises Ti₃C₂Tₓ, wherein Tₓ is a functional group comprising —OH, —F, or —O. MXene generally exhibits excellent electrical conductivity. For example, the electrical conductivity of Ti₃C₂Tₓ MXene is about one of order magnitude lower than copper. The MXene termination layer Tₓ (—OH, —F, —O etc.) produces negatively charged hydrophilic surfaces. Another advantage of MXene is that the hydrophilic surfaces in the termination layer can adhere or attach to the surface of polymer hydrogels through the formation of a unique clay-polymer network structure that is cross-linked with uniformly dispersed clays and densely entangled polymer chains. Moreover, the high density of surface functional groups, such as —OH, can increase the number of hydrogen bonds in the polymer hydrogel system, which advantageously improves the self-healing capability of polymer hydrogels.

The cooperative effect of polymer hydrogel liner 450 and MXene seed layer 460 provides advantages compared with a Ti/Cu seed layer on sidewalls of holes 220 in glass 210. Polymer hydrogel liner 450 exhibits good adhesion to the glass sidewall. For example, polymer hydrogel liner 450 adheres to glass better than a Ti/Cu seed layer. In addition, polymer hydrogel liner 450 accommodates stresses that may develop between the glass and subsequently deposited metallization. Further, MXene seed layer 460 provides good electrical conductivity, which is necessary for electrodeposition of metallization. In some examples, MXene seed layer 460 has an elastic modulus in a range of 604 to 454 GPa.

Referring again to FIG. 1C, the polymer hydrogel liner 450 and the MXene seed layer 460 may be removed from front-side and back-side surfaces 241, 242 of glass 210 at block 135. In addition, front-side and back-side surfaces 241, 242 may be planarized and/or polished using chemical mechanical polishing (CMP) methods.

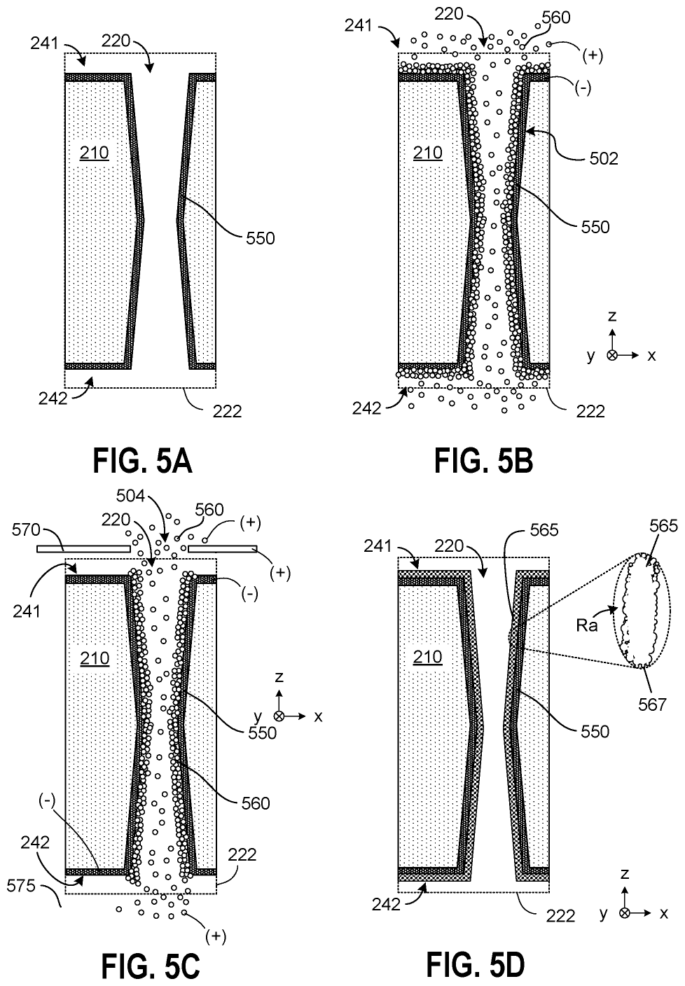

FIG. 1D illustrates methods for depositing a liner upon sidewalls of features formed into a bulk glass according to some embodiments. The liner comprises a polymer having a low elastic modulus. The polymer liner may be formed only upon a sidewall of through holes 220, or upon both sidewalls of the holes and over a surface of the glass between the through holes. The methods for depositing a liner illustrated in FIG. 1D employ electrodeposition. The methods require glass 210 to be coated with a conductive seed layer, so that the conductive seed layer can be biased with an electrical charge during electrodeposition of liner material. The methods may begin with a conductive seed layer being deposited upon surfaces of glass 210 at block 137. Some operations of the methods of FIG. 1D are illustrated using representative portion 222 in FIGS. 5A, 5B, 5C, and 5D.

FIG. 5A illustrates an example of a conductive seed layer 550 that has been deposited upon surfaces of glass 210. In some embodiments, surfaces of glass 210 comprises a layer of indium tin oxide (ITO) on its surfaces. ITO coated glass panels are electrically conductive. In some embodiments, conductive seed layer 550 is comprised of copper (Cu), or an alloy of titanium (Ti) and copper, such as TiCu. Conductive seed layer 550 may be applied using any suitable deposition process, e.g., PVD, CVD, or ALD. The seed material can be deposited over front-side and back-side surfaces 241, 242 and within holes 220, as shown in the figure. Alternatively, deposition of the seed material can be tailored to only be deposited where desired, e.g., on sidewalls of through holes 220. In another alternative, the seed material can be selectively removed after deposition from areas where it is not desired, e.g., front-side and back-side surfaces 241, 242.

Referring to FIG. 1D, in one alternative, a hard mask is positioned over a surface of glass 210 at block 139. In other alternatives, a hard mask is not used and block 139 is omitted. FIG. 5B illustrates an example in which use of a hard mask is omitted and charged polymer nanoparticles 560 have been deposited upon front-side and back-side surfaces 241, 242, and on sidewalls 502 of through holes 220. FIG. 5C illustrates an example in which a hard mask 570 is positioned over surface 241 of glass 210 and charged polymer nanoparticles 560 have been deposited upon sidewalls of through holes 220. As shown in FIG. 5C, charged polymer nanoparticles 560 may be substantially absent from front-side surface 241 when a hard mask is employed. Use of a hard mask may also reduce the quantity of polymer nanoparticles 560 on back-side surface 242. A hard mask refers to a material used in place of a polymer or other soft resist material as an etch mask. Example hard mask materials include silicon dioxide, silicon carbide, amorphous carbon, titanium nitride, and tantalum nitride. Hard mask 570 may be a thin dielectric material with a conductive coating, e.g., Cu. Hard mask 570 includes openings 504 positioned to correspond with positions of respective through holes 220. Openings 504 in hard mask 570 may have a shape and dimensions similar to the x-y shape and x-y dimensions of through holes 220 at front-side and back-side surfaces 241, 242, The hard mask 570 is positioned so that the openings 504 are aligned with the through holes at block 139. Hard mask 570 is positioned above glass 210 so as to be close to, but to not in contact with glass 210. Hard mask 570 may be reusable. Mask geometry, spacing, voltage, particle size distribution, aerosol density, and time parameters may be adjusted to tune the thickness and other attributes of the deposited layer of nanoparticles. In some examples, an additional voltage source (not shown) may be positioned below glass 210 to further tune the velocity of the nanoparticles, and thus the speed of the deposition process. Further, voltage sources may be varied with time to ensure even nanoparticle coverage.

Referring again to FIG. 1D, glass 210 or conductive seed layer 550 is biased to a polarity at block 140. In examples in which hard mask 570 is employed, hard mask 570 is also biased at block 140. Charged polymer nanoparticles are deposited on sidewalls of through holes 220 at block 141. Charged polymer nanoparticles may be deposited via a solution or an aerosol.

FIGS. 5B and 5C illustrate examples in which charged polymer nanoparticles 560 have been deposited on sidewalls of through holes 220. In the example of FIG. 5B, charged polymer nanoparticles have also been deposited upon both front-side and back-side surfaces 241, 242 of glass 210. In the example of FIG. 5B, charged polymer nanoparticles 560 may have been deposited by immersing glass 210 in a solution containing the charged polymer nanoparticles. In the example of FIG. 5C, charged polymer nanoparticles 560 may have been deposited by exposing glass 210 to an aerosol containing the charged nanoparticles. While nanoparticles 560 are depicted as spherical, this is for convenience of illustration only, and the nanoparticles 560 may be any of a variety of known shapes.

In the examples of FIGS. 5B and 5C, glass 210 or conductive seed layer 550 has a negative charge (−) and polymer nanoparticles 560 may have a positive charge (+). In FIG. 5C, hard mask 570 also has a positive charge (+). Alternatively, in another example, glass 210 or conductive seed layer 550 may have a positive charge (+) and polymer nanoparticles 560 may have a negative charge (−). In this alternative example, if hard mask 570 is employed, hard mask 570 has a negative charge (−).

The polarity of charged nanoparticles may be positive or negative, provided the polarity of glass 210 or conductive seed layer 550 is selected to be the opposite polarity. This is so the charged nanoparticles will be attracted to oppositely charged glass 210 or conductive seed layer 550. In addition, whatever polarity is provided to glass 210 or conductive seed layer 550, an opposite polarity is provided to hard mask 570. This is so the charged nanoparticles will be repelled from the like-charged hard mask. In examples in which a high-ion (low resistivity) glass is used, a higher bias voltage may be required than in examples where conductive seed is used.

In some embodiments, charged polymer nanoparticles 560 are provided in a solution. Glass 210 is clamped with electrodes and immersed into the solution containing charged polymer nanoparticles 560. The solution may contain other components, such as surfactants to prevent unwanted nanoparticle aggregation, acids to remove undesired contaminants and oxides, and “brighteners,” “accelerators,” and “levelers” to promote uniform coating. Preferably, the solution contains polymer nanoparticles 560 having a wide variety of sizes to ensure a high density of the coating.

In some embodiments, charged polymer nanoparticles 560 are provided in an aerosol. An aerosol containing charged nanoparticles 560 is introduced from the top-down, e.g., at first surface 241. If a hard mask 570 is employed in conjunction with a top-down approach, an aerosol may first be introduced from above with the hard mask 570 over surface 241, the glass 210 may be flipped, and then further aerosol may be introduced from above with the hard mask 570 over surface 242. Flipping glass 210 and repeating the aerosol introduction operation may provide a symmetric liner thickness profile. In some embodiments, a bi-directional approach may be used, e.g., aerosol may be introduced from above and below in separate passes. Top-side and bottom-side applications of the aerosol may enhance uniformity of particle deposition. In examples in which hard mask 570 is employed, electrostatic forces “guide” charged nanoparticles 560 through the openings in hard mask 570 and to sidewalls of through holes 220 due to repulsive forces of the hard mask and attractive forces of glass 210 or conductive seed layer 550. An advantage of exposing glass 210 to an aerosol covered with hard mask 570 is that the charged particles will be directed to the sidewalls of through holes 220, rather than passing through the holes without coating them. Polymer nanoparticles may also be substantially absent from front-side and back-side surfaces 241, 242. Another advantage of employing hard mask 570 and exposing glass 210 to an aerosol is that the thickness of the resulting polymer liner may tuned for a particular application without need for photolithography.

The polymer nanoparticles 560 may be comprised of any thermoplastic material suitable for buffering stress between the glass sidewall of through hole 220 and via metallization. The polymer nanoparticles 560 may be any suitable polymer that has a low elastic modulus when annealed or cured into a film. While the polymer material in the example methods described with respect FIG. 1D is referred to herein as “polymer nanoparticles” 560, it should be appreciated that this is for convenience and the polymer need not be limited to nanoscale particles. While the size of nanoparticles of which polymer nanoparticles 560 is comprised is typically between 1 nm and 100 nm, in some embodiments, the nanoparticles may be between 100 nm and 2.5 μm, or between 1 μm and 1000 μm.

The polymer nanoparticles 560 may include a base polymer and one or more of a variety of different functional groups. Some example base polymers may include polypropylene, polyethylene, acrylics, and the like. In various embodiments, the base polymer may be any high temperature thermoplastic polymer, such as polyether ether ketone (PEEK), polyethylenimine (PEI), polyamide-imides (PAI), polyphenylene sulfide (PPS), polyether sulfones (PES), polyphenylsulfone (PPSU), liquid crystal polymers (LCPs), polytetrafluoroethylene (PTFE), ethylene tetrafluoroethylene (ETFE), and associated families. Whether the polymer nanoparticles 560 are positively or negatively charged generally depends on the functional group selected. If positively charged polymer nanoparticles are desired, the polymer can incorporate ammonium, sulfonium, phosphonium, or similar functional groups. If negatively charged polymer nanoparticles 560 are desired, the charged polymer nanoparticles can incorporate carboxylic acid, phosphoric acid, sulfonic acid, or similar functional groups. Any functional group providing the base polymer with the desired charge may be used, as embodiments are not limited to the example functional groups listed herein.

Referring again to FIG. 1D, glass 210 may be heated to anneal polymer nanoparticles 560 into a continuous, thin film at block 143. FIG. 5D illustrate an example in which polymer nanoparticles have been annealed into polymer film 565 on sidewalls of through holes 220 and on front-side and back-side surfaces 241, 242. If glass 210 was immersed in a solution of polymer nanoparticles 560 at block 141, the glass may be dried prior to heating. In some examples, an annealing oven is heated to a temperature in the range of 300-350 C. An advantage of annealing polymer nanoparticles 560 is that it imparts a tensile stress into the polymer film as it cools. Tensile stress is helpful not just in adhesion of the film 565 to glass 210, but in counteracting compressive stress that occurs within a fully copper-plated through glass via as temperature increases. In an alternative embodiment, polymer nanoparticles 560 are partially cured into a porous film. This may improve the ability of the polymer film to act as a stress buffer. In some embodiments, the polymer film 565 has an elastic modulus below 20 GPa.

Film 565 is comprised of annealed or cured polymer nanoparticles 560. Film 565 may have a “bumpy” surface, as may be seen in cross-section 567. As noted, polymer nanoparticles 560 may comprises particles of multiple different sizes, and an average roughness Ra of the surface film 565 will vary depending on the size(s) of the charged polymer nanoparticles 560. In various embodiments, a surface of film 565 may have an average surface roughness of between about 10 nm and about 500 nm. In some embodiments, a surface of film 565 may have an average surface roughness of between about 10 nm and about 100 nm. In other examples, a surface of film 565 may have an average surface roughness of between about 10 nm and about 200 nm. In other examples, a surface of film 565 may have an average surface roughness of between about 10 nm and about 300 nm, or 400 m nm.

In some embodiments, two or more layers of charged polymer nanoparticles 560 may be deposited within a though hole. As described above, polymer nanoparticles 560 are deposited on glass 210 at block 141, and the polymer nanoparticles 560 may be annealed into polymer film 565 at block 143. In some examples, the deposition of polymer nanoparticles 560 at block 141 and/or the annealing polymer nanoparticles into polymer film 565 may be repeated one or more times, as indicated in FIG. 1D, by an arrow from block 141 to block 140, and by an arrow from block 143 to block 140. After a first layer of charged polymer nanoparticles 560 is deposited, the first layer may be annealed at block 143. Subsequent to annealing, a second layer of charged polymer nanoparticles 560 may be deposited at block 141. The depositing and annealing steps may be repeated for additional layers. Each alternating layer of polymer nanoparticles 560 may have a different polarity. For example, a first layer of charged polymer nanoparticles 560 may have a positive polarity and a second layer of charged polymer nanoparticles 560 may have a negative polarity. During deposition of the first layer, hard mask 570 is biased with a positive polarity while glass 210 or conductive seed layer 550 is biased with a negative polarity, which attracts the positively charged particles. After annealing the first layer, a second layer of negatively charged polymer nanoparticles 560 is deposited. During deposition of the second layer, hard mask 570 is biased with a negative polarity while glass 210 or conductive seed layer 550 is biased with a positive polarity. Depositing multiple layers of alternating positive and negative polymer nanoparticles may allow polymer film 565 to be built up into a thicker film than where the nanoparticles have the same charge. After an initial layer is deposited, an attempt to deposit a second layer of like-charged polymer nanoparticles would encounter repulsive forces. Similarly, after an initial quantity of particles of one layer are deposited, an attempt to deposit a further quantity of like-charged polymer nanoparticles on the layer would encounter repulsive forces. Accordingly, a thicker liner than might otherwise be deposited may be obtained by depositing two or more layers of polymer nanoparticles 560, where each subsequently deposited layer has the opposite polarity of the previously deposited layer. While it may be preferable to thermally anneal polymer nanoparticles after each layer is deposited, in some examples two or more layers of alternating positive and negative polymer nanoparticles may be deposited without an intervening thermally annealing operation. An advantage of increasing the thickness of polymer film 565 by depositing multiple layers of particles is increased mechanical strength and increased capability to buffer stress between glass and via metallization.

Referring again to FIG. 1D, a conductive seed may be deposited on the liner comprising nanoparticle polymer film 565 at block 145. (The conductive seed layer is not shown in FIG. 5D.) The conductive seed layer may serve as an electrode during electrodeposition of a metal, e.g., Cu to fill through holes 220 to form through glass vias. The conductive seed layer comprises Cu or Ti/Cu. In some embodiments, the conductive seed layer comprises an MXene seed layer, such as Ti₃C₂Tₓ MXene.

FIG. 1E illustrates methods for depositing a liner comprising two layers upon sidewalls of features formed into a bulk glass according to some embodiments. The two layers comprise an organic material layer and a metal layer. The metal layer may include a metal with a low elastic modulus, such as aluminum or tin. The organic material layer may include an organic material with a low elastic modulus, such as an-epoxy based dielectric, with or without inorganic filler, a polyimide, or a parylene. The elastic modulus of the organic material layer may be less than 3.0 GPa. In some embodiments, the elastic modulus of the organic material layer may be less than 15 GPa. Individually, the organic material layer and the metal layer each reduce stress that develops between the glass and via metallization. Advantageously, a liner that includes both an organic material layer and a metal layer may reduce internal stress between the glass and via metallization by an amount that is greater than the stress reduction provided by either layer individually. The organic material layer may be deposited on the glass with the metal layer deposited over the organic material layer. Alternatively, the metal layer may be deposited on the glass with the organic material layer deposited over the metal layer. Some operations of the methods of FIG. 1E are illustrated using representative portion 222 in FIGS. 6A, 6B, 6C, and 6D.

Referring to FIG. 1E, an organic material layer is deposited upon surfaces of glass features formed into a bulk glass at 147. FIG. 6A illustrates an example of an organic material layer 650 that has been deposited upon sidewalls 602 of through holes 220 and front-side and back-side surfaces 241, 242 of glass 210. The organic material layer 650 may be formed by vapor deposition, slit/spray coating, or vacuum lamination. Organic material layer 650 may have a thickness between 1 and 10 μm in various embodiments.

Referring again to FIG. 1E, a metal layer is deposited over the organic material layer at 149. FIG. 6B illustrates an example of a metal layer 660 that has been deposited upon surfaces of organic material layer 650. The metal layer 660 may be formed by PVD, e.g., sputter deposition, or ALD. The metal layer may have a thickness between 0.1 and 2 μm in various embodiments. In the example shown in FIG. 6B, organic layer 650 is between the metal layer 660 and a sidewall 602 of through hole 220. Optionally, to facilitate metallization of the TGV, a conductive seed layer may be deposited upon metal layer 660. FIG. 6C illustrates an example of a conductive seed layer 662 that has been deposited upon surfaces of metal layer 660. Conductive seed layer 662 may comprise Cu, Ti/Cu, or an MXene, such as Ti₃C₂Tₓ MXene.

Referring again to FIG. 1E, in an alternative, metal layer is deposited upon surfaces of glass features formed into a bulk glass at 151. An organic material layer is deposited over the metal material layer at 153. A conductive seed layer is deposited over the organic material layer at 155. FIG. 6D illustrates an example of a metal layer 660 that has been deposited upon surfaces of glass 210 (including sidewall 602), an organic material layer 650 that has been deposited over the metal layer 660, and a conductive seed layer 662 that has been deposited upon surfaces of organic material layer 650. The metal layer 660 may be formed by VPD, e.g., sputter deposition, or ALD. The metal layer may have a thickness between 0.1 and 2 μm in various embodiments. The organic material layer 650 may be formed by vapor deposition, slit/spray coating, or vacuum lamination. Organic material layer 650 may have a thickness between 1 and 10 μm in various embodiments. Conductive seed layer 662 may comprise Cu, Ti/Cu, or an MXene, such as Ti₃C₂Tₓ MXene. In the example shown in FIG. 6D, the metal layer 660 is between the organic material layer 650 and sidewall 602 of through hole 220 in glass 210.

FIG. 1F illustrates methods for depositing a liner upon sidewalls of the features formed into a bulk glass according to some embodiments. The liner comprises three layers: a first metal layer, a second metal layer, and an organic material layer between the first and second metal layers. The first metal layer may be in direct contact with sidewalls of the through holes, while the second metal layer may be in direct contact with via metallization, such as Cu. As noted above, a glass core with fully filled copper vias can have mechanical and electrical reliability issues. Copper filled TGVs decrease the failure stress of a layer of the glass. The strength of the glass may be partially or completely recovered by decoupling the copper from the glass sidewalls with a low elastic modulus liner. For example, an organic material layer may act to cushion the glass when copper metallization expands more than the glass. However, one issue that may arise with some organic liners is that when copper contracts the organic liner may fail to adhere to the copper due to cohesion failure. An advantage of a three-layer liner is that second metal layer, which is in contact with via metallization, may protect the organic material layer from being pulled apart or away from the metallization. In embodiments, first metal layer, second metal layer, or both first and second metal layers may have an elastic modulus that is low, but which is higher than the organic material layer. The first and/or second metal layers may withstand forces exerted by metal contraction during cooling without cohesive failure, while the organic material layer absorbs stress during metal expansion. The first and/or second metal layers may also absorb stress during metal expansion. Another advantage of the second metal layer is that it may facilitate electroplating of Cu within the through holes as it is conductive. In some embodiments, a conductive seed layer over the second metal layer is not required.

The first metal layer may be one of aluminum (Al), tin (Sn), scandium (Sc), indium (In), or titanium (Ti). Aluminum is particularly advantageous because of its low modulus of elasticity, however, any metal or alloy with a suitably low modulus of elasticity may be used. The second metal layer may be the same material as the first metal layer, or a different material. The second metal layer may be one of Al, Sn, Sc, In, or Ti. Exemplary metals Al, Sn, Sc, and In all have an elastic modulus below 80 GPa. The elastic modulus of Ti is about 120 GPa. In various embodiments, the elastic modulus of first metal layer may be less than 80 GPa, or less than 120 GPa. Similarly, the elastic modulus of second metal layer may be less than 80 GPa, or less than 120 GPa. In some embodiments, the first and second metal layer each comprise an alloy, wherein each alloy comprises at least two of Al, Sn, Sc, In, or Ti. The organic material layer may be an epoxy-based dielectric, with or without inorganic filler, a polyimide, or a parylene, or other suitable organic or inorganic material. The elastic modulus of polyimide is about 2.5 GPa. The elastic modulus of parylene is about 3.0 GPa. The elastic modulus of epoxy without filler is less than 3.0 GPa. With filler, the elastic modulus of epoxy may be less than 10 GPA. In various embodiments, the elastic modulus of the organic material layer may be less than 3.0 GPA, or less than 10 GPa. Some operations of the methods of FIG. 1F are illustrated using representative portion 222 in FIGS. 7A, 7B, 7C, and 7D.

Referring to FIG. 1F, a first metal layer is deposited upon sidewalls of through holes, and over a surface of the glass between the through holes at block 157. The first metal layer may be deposited using a PVD process. FIG. 7A illustrates an example of first metal layer 750 that has been deposited upon surfaces of glass 210, e.g., front-side and back-side surfaces 241, 242, and sidewalls 702. In the example of FIG. 7A, first metal layer 750 may comprise aluminum.

Referring again to FIG. 1F, an organic material layer is deposited over the first metal layer at block 159. FIG. 7B illustrates an example of organic material layer 760 that has been deposited over first metal layer 750. The organic material layer may be deposited using a lamination or slit coating process. In the example of FIG. 7A, organic material layer 760 may comprise parylene.

Referring again to FIG. 1F, a second metal layer is deposited over the organic material layer at block 161. The second metal layer may be deposited using a PVD process. FIG. 7C illustrates an example of second metal layer 762 that has been deposited upon organic material layer 760. In the example of FIG. 7C, second metal layer 762 may comprise aluminum.

Thicknesses of first and second metal layers 750, 762, and organic material layer 760 may vary with implementation. In exemplary embodiments, first and second metal layers 750, 762 may have a thickness between 0.1 and 2 μm. In exemplary embodiments, organic material layer 760 may have a thickness between 1 and 10 μm.

In some embodiments, an optional conductive seed layer may be deposited upon the second metal layer. FIG. 7D illustrates an example of conductive seed layer 764 that has been deposited upon second metal layer 762. Conductive seed layer 764 may comprise Cu or Ti/Cu. In some embodiments, the conductive seed layer 764 comprises an MXene seed layer, such as Ti₃C₂Tₓ MXene. In some examples, through holes 220 may be drilled after deposition of the second metal layer (and optional conductive seed layer) and prior to metallization.

Returning to FIG. 1A, methods 101 continue at block 165 where a suitable metal is deposited over the liner and within the through holes to form electrically conductive through vias, which may be referred to as through substrate vias (TSVs) or more particularly through glass vias (TGVs). The via metallization is then planarized at block 170 to remove overburden associated with the plating process and/or remove the liner from front and back sides of the glass.

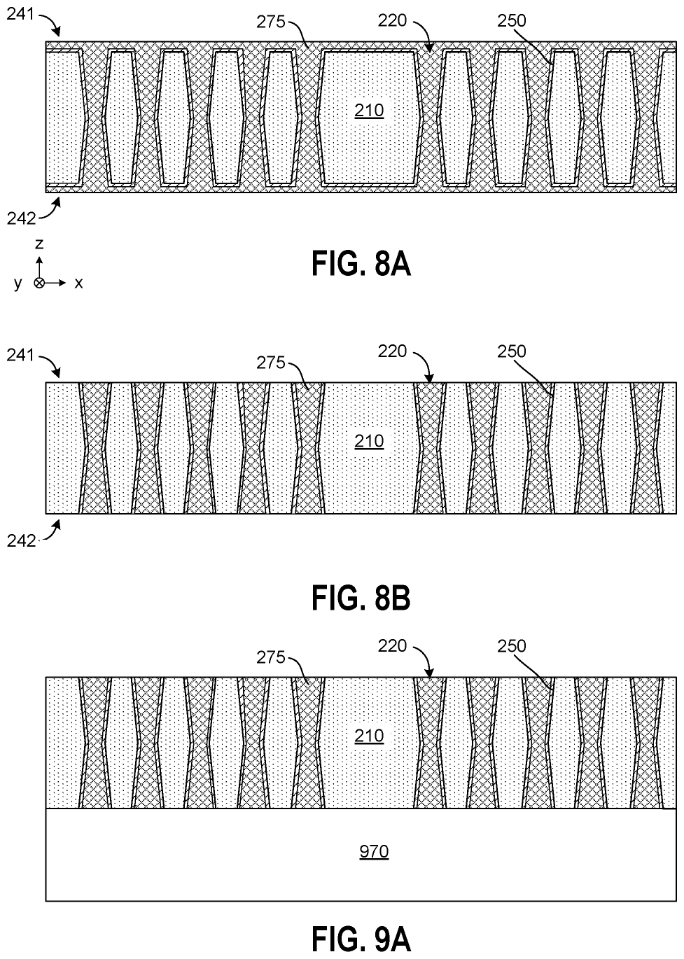

In the example further illustrated in FIG. 8A, a via metallization 275 has been deposited over front-side and back-side surfaces 241, 242, as well as into through holes 220. Via metallization 275 is in direct contact with liner 250 and may, but need not, substantially fill through holes 220. It should be understood that liner 250 may be any of the liners described herein. In some examples, via metallization 275 is one or more metals (e.g., predominantly copper) deposited (e.g., electroplated) upon surfaces of the workpiece covered by the liner. Via metallization 275 may have a significantly higher elastic modulus and/or CTE than the various layers described herein that may comprise liner 250. Via metallization of predominantly Cu, for example, can be expected to have an elastic modulus of around 130 GPa and a CTE of 16-17 ppm/K. FIG. 8B further illustrates a workpiece after planarization of front-side and back-side surfaces 241, 242. As shown, following planarization, via metallization 275 and liner 250 remains only adjacent to sidewalls of glass 210. Workpiece in FIG. 6B can also be obtained by chemical metal etch processes without incorporating mechanical abrasion in planarization.

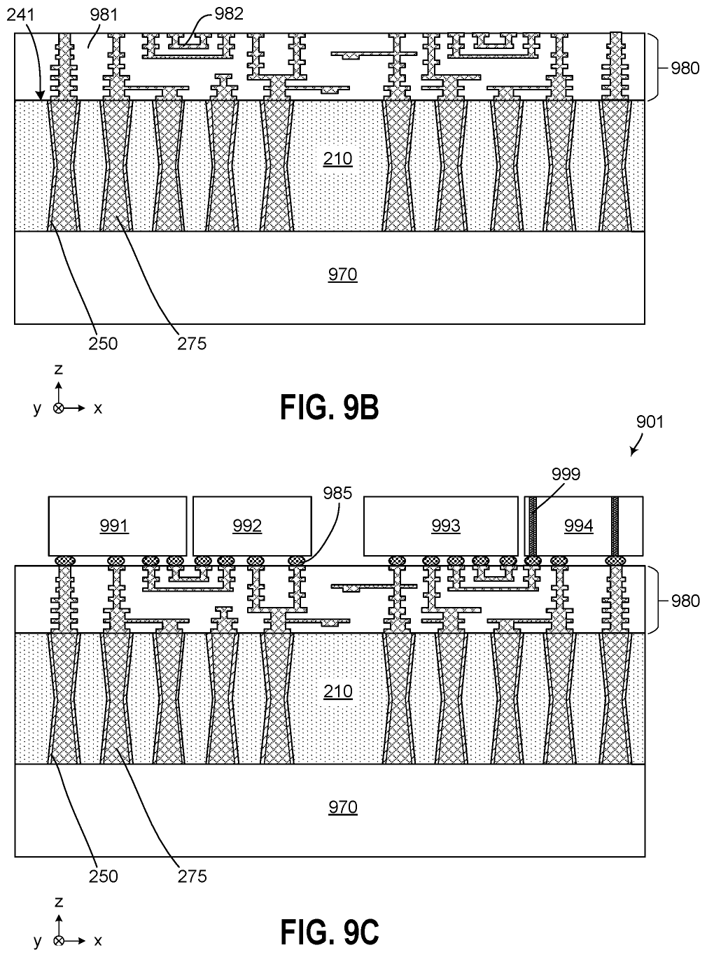

After the formation of conductive through vias, glass 210 may be affixed to a handle or carrier 970, as further depicted in FIG. 9A. Carrier 970 may have any suitable composition and be of any suitable thickness, as embodiments herein are not limited in this context.

Returning to FIG. 1A, methods 101 continue at block 175 where an electrical routing structure is built up over at least one side of the glass prior to assembly with IC die. The electrical routing structure may be electrically coupled to the through vias and may, for example, comprise one or more levels of metallization features embedded within any suitable dielectric material. The electrical routing structure formed at block 175 may interconnect one or more IC die to each other and/or couple one or more of IC die to the conductive through vias. Accordingly, the metallization feature pitch of the routing structure is advantageously minimized for highest interconnect density.

In the example illustrated in FIG. 9B, a routing structure 980 has been built-up over front-side surface 241. Routing structure 980 comprises one or more levels of RDL metallization features 982 embedded within one or more layers of dielectric material 981. RDL metallization features 982 may comprise one or more metals, with one example being predominantly copper. At least some of RDL metallization features 982 are to electrically bridge together two or more IC dies, preferably with the finest metallization line: space feature pitch that can be directly patterned (e.g., <3 μm lines and spaces) as enabled by the improved flatness profile of glass 210 compared to traditional organic preform cores. Routing structure 980 further comprises metallization features 982 that are to interconnect multiple IC dies to conductive TGVs.

Depending on the embodiment, dielectric material 981 may be any of a molding compound, a spin-on material, or dry film laminate material, for example. Dielectric material 981 may be introduced wet/uncured into a cast and then dried/cured. Alternatively, dielectric material 981 may be introduced as a semi-cured dry film that is fully cured following its application to glass 210.

The composition of dielectric material 981 may vary with implementation. In some advantageous embodiments, dielectric material 981 is an organic dielectric, such as, an epoxy resin, phenolic-glass, or a resinous film such as the GX-series films commercially available from Ajinomoto Fine-Techno Co., Inc. (ABF). Dielectric material 981 may comprise epoxy resins (e.g., an acrylate of novolac such as epoxy phenol novolacs (EPN) or epoxy cresol novolacs (ECN)). In some specific examples, dielectric material 981 is a bisphenol-A epoxy resin, for example including epichlorohydrin. In other examples, dielectric material 981 includes aliphatic epoxy resin.

Returning to FIG. 1A, methods 101 continue at block 180 where at least one IC die is assembled to the workpiece and, more particularly, to the electrical routing structure that was formed at block 175. IC die assembled at block 180 may each comprise any electrical circuitry, with one example being logic circuitry comprising logic gates. IC die assembled at block 180 may also comprise any photonic circuitry suitable for the detection, emission or processing (e.g., filtering, multiplexing and demultiplexing) of optical signals.

In the example illustrated in FIG. 9C, IC die 991-994 are assembled to interconnect interfaces within a top metallization level of routing structure 980 as the first die of a co-packaged multi-die IC device package structure 901. IC die 991-994 may be directly bonded to routing structure 980, or, electrically coupled through intervening electrical interconnects 985, which may comprise solder of any suitable composition. In the example illustrated, IC die 991-993 are each flip-chip attached with integrated circuitry within each die being proximal to front-side surface 241. IC die 994 however comprises through die vias 999 with integrated circuitry being distal from front-side surface 241.

Each of IC die 991-994 may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, one or more of IC die 991-994 include one or more banks of active repeater circuitry to improve multi-die interconnects (e.g., network-on-chip architectures). In other examples, one or more of IC die 991-994 includes clock generator circuitry or temperature sensing circuitry. In other examples, one or more of IC die 991-994 include logic circuitry that, along with other IC die 991-994 implement multi-chiplet aggregated logic circuitry (e.g., mesh network-on-chip architectures). In some specific examples, at least one of IC die 991-994 includes microprocessor core circuitry, for example comprising one or more shift registers.

IC die 991-994 advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die 991-994 may include active devices other than FETs. For example, IC die 991-994 may include electronic memory structures, such as magnetic tunnel junctions (MTJs), capacitors, or the like.

IC die 991-994 may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 991-994 may have a feature pitch ranging from 100 nm to several microns, for example.

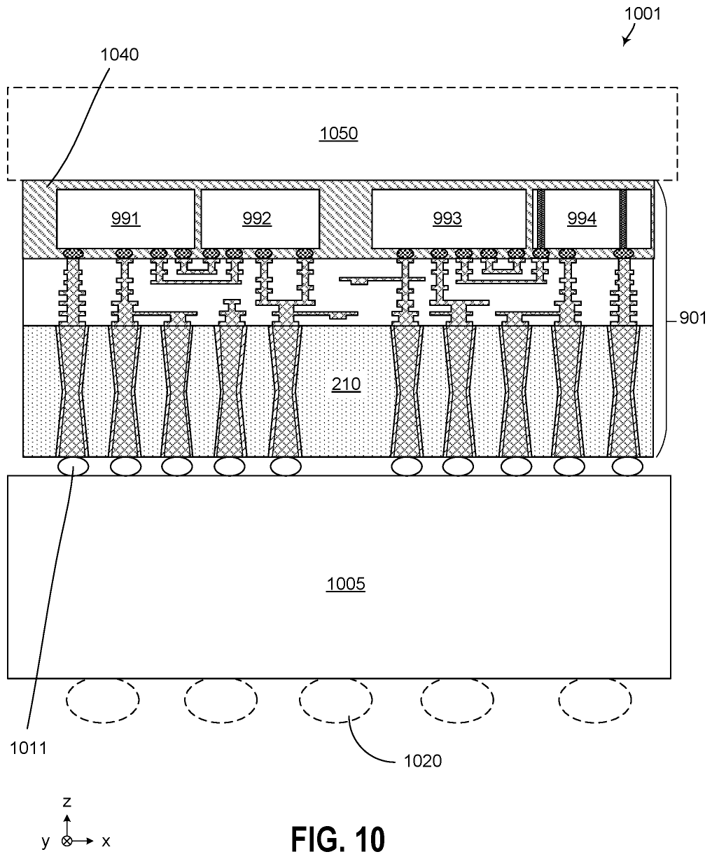

Returning to FIG. 1, methods 101 complete at output 190 where the assemble device package structure is attached to any suitable host component. FIG. 10 illustrates an exemplary system 1001 including one device package structure 901 attached to a host component 1005 with interconnects 1011, in accordance with some embodiments. In exemplary embodiments, interconnects 1011 are solder (e.g., SAC) microbumps although other interconnect features are also possible. In some embodiments, host component 1005 is predominantly silicon. Host component 1005 may also comprise one or more alternative materials known to be suitable as interposers or package substrates (e.g., an epoxy preform, cored or coreless laminate board, etc.). Host component 1005 may also include a printed circuit board (PCB). Host component 1005 may include one or more metallized redistribution levels (not depicted) embedded within a dielectric material. Host component 1005 may also include one or more IC die embedded therein.

Host component 1005 may include interconnects 1020 illustrated in dashed line. Interconnect 1020 may comprise any solder (ball, bump, etc.) suitable for a given host board architecture (e.g., surface mount FR4, etc.). Also illustrated in dashed line, one or more heat spreaders and/or heat sinks 1050 may be further coupled to device package structure 901, which may be advantageous, for example, where IC dies 991-994 comprise one or more CPU cores or other circuitry of similar power density. Any package dielectric 1040, such as a mold material, may surround sidewalls of IC dies 991-994. Although not illustrated, package dielectric 1040 may be background so that heat spreader/sink 1050 may be in closer contact with IC dies 991-994,

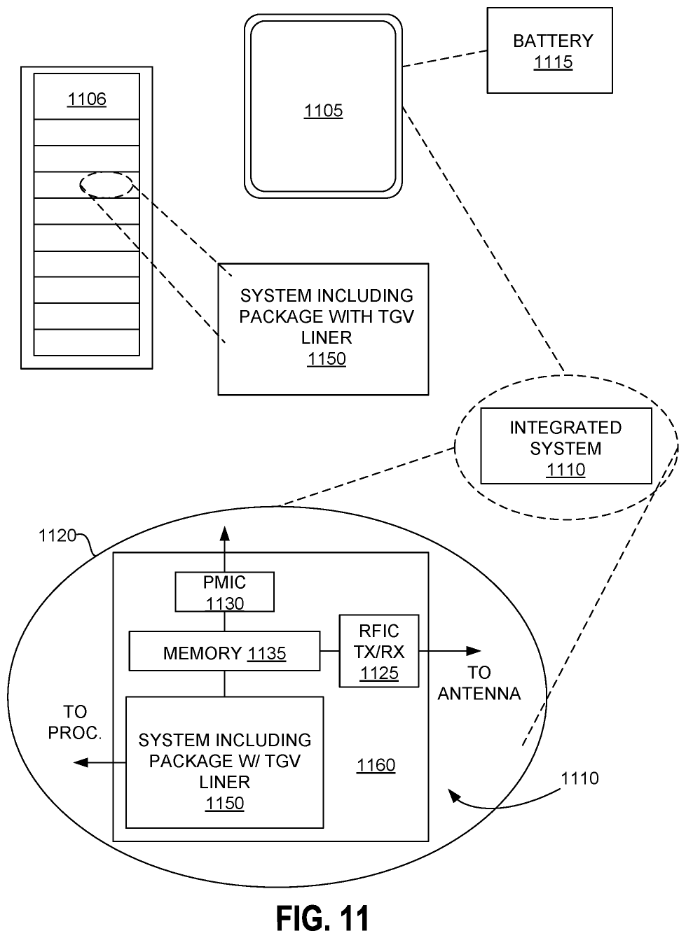

FIG. 11 illustrates a mobile computing platform and a data server machine employing one or more device package structures, for example as described elsewhere herein. For example, mobile computing platform 1105 or server machine 1106 may include device package structure device package structure 901 or system 1001. Server machine 1106 may be any commercial server, for example including any number of high-performance computing platforms disposed within a rack and networked together for electronic data processing, which in the exemplary embodiment includes a substrate comprising glass and a plurality of TGVs extending through the glass, wherein the TGVs comprise one or more of the liners described elsewhere herein. The mobile computing platform 1105 may be any portable device configured for each of electronic data display, electronic data processing, wireless electronic data transmission, or the like. For example, the mobile computing platform 1105 may be any of a tablet, a smart phone, laptop computer, etc., and may include a display screen (e.g., a capacitive, inductive, resistive, or optical touchscreen), a chip-level or package-level integrated system 1110, and a battery 1115.

Whether disposed within the integrated system 1110 illustrated in the expanded view 1120, or as a stand-alone package within the server machine 1106, the integrated system or server machine includes system 1001, wherein the system includes device package structure device 901, which includes a glass substrate having a plurality of TGVs, the TGVs comprising one or more of the liners described elsewhere herein. For example, system 1150 may comprise system 1001, which is described elsewhere herein. System 1150 may be further coupled to a host substrate 1160, along with, one or more of a power management integrated circuit (PMIC) 1130, RF (wireless) integrated circuit (RFIC) 1125 including a wideband RF (wireless) transmitter and/or receiver (TX/RX) (e.g., including a digital baseband and an analog front-end module further comprises a power amplifier on a transmit path and a low noise amplifier on a receive path), and a memory 1135. PMIC 1130 may perform battery power regulation, DC-to-DC conversion, etc., and so has an input coupled to battery 1115 and with an output providing a current supply to other functional modules. As further illustrated, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

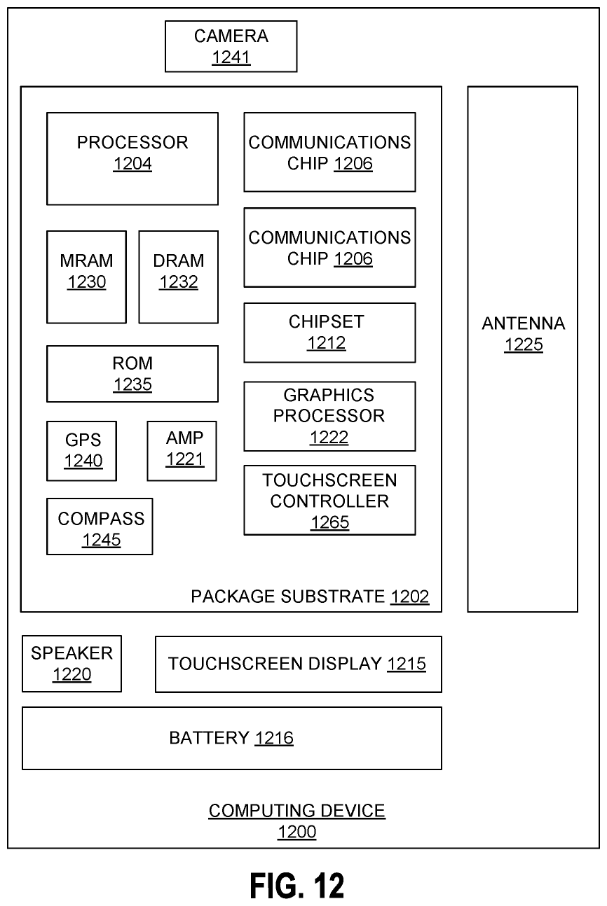

FIG. 12 is a functional block diagram of an electronic computing device 1200, in accordance with an embodiment of the present invention. The computing device may include IC device package structures comprising glass substrates with TGVs with liners between glass and via metallization, as described herein. Device 1200 further includes a package substrate 1202 hosting a number of components, such as, but not limited to, a processor 1204 (e.g., an applications processor). Processor 1204 may be physically and/or electrically coupled to package substrate 1202. In some examples, processor 1204 is within system 1001, for example, as described elsewhere herein. Processor 1204 may be implemented with circuitry in either or both of the host IC chip and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 1206 may also be physically and/or electrically coupled to the package substrate 1202. In further implementations, communication chips 1206 may be part of processor 1204. Depending on its applications, computing device 1200 may include other components that may or may not be physically and electrically coupled to package substrate 1202. These other components include, but are not limited to, volatile memory (e.g., DRAM 1232), non-volatile memory (e.g., ROM 1235), flash memory (e.g., NAND or NOR), magnetic memory (MRAM 1230), a graphics processor 1222, a digital signal processor, a crypto processor, a chipset 1212, an antenna 1225, touchscreen display 1215, touchscreen controller 1265, battery 1216, audio codec, video codec, power amplifier 1221, global positioning system (GPS) device 1240, compass 1245, accelerometer, gyroscope, speaker 1220, camera 1241, and mass storage device (such as hard disk drive, solid-state drive (SSD), compact disk (CD), digital versatile disk (DVD), and so forth), or the like. In some exemplary embodiments, two or more of the functional blocks noted above are within device package structure 901, which includes a glass core having TGVs comprising one or more of the liners described elsewhere herein. For example, processor 1204 may be implemented within circuitry in a first IC die 991, and an electronic memory (e.g., MRAM 1230 or DRAM 1232) 992 may be implemented with circuitry in a second IC die.

Communication chips 1206 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1206 may implement any of a number of wireless standards or protocols. As discussed, computing device 1200 may include a plurality of communication chips 1206. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus, comprising: a substrate comprising glass and a plurality of holes extending through the glass; a via metallization within each of the holes; and a metallic layer within the holes, wherein: the metallic layer is between the via metallization and the glass; and the metallic layer comprises titanium and niobium.

Example 2: The apparatus of example 1, wherein the metallic layer further comprises tantalum and zirconium.

Example 3: The apparatus of any of examples 1 or 2, wherein the metallic layer comprises an elastic modulus less than 40 GPa.

Example 4: The apparatus of any of examples 1 or 2, wherein the metallic layer comprises an elastic modulus in a range of 25 to 35 GPa.

Example 5: The apparatus of any of examples 1, 2 or 3, further comprising a conductive seed layer between the metallic layer and the via metallization.

Example 6: The apparatus of any of examples 1 or 2, or 3 or 5, wherein the metallic layer has a maximum thickness of 4 μm.

Example 7: The apparatus of any of examples 1 or 2, or 3 or 5, wherein the metallic layer has a maximum thickness of 1 μm.

Example 8: The apparatus of any of examples 1 or 2, or 3 through 6, wherein the via metallization comprises Cu.

Example 9: A system comprising: a plurality of integrated circuit (IC) die electrically coupled to first metallization features on a first side of a substrate comprising glass; a plurality of holes extending through the glass; via metallization within the holes, the via metallization to electrically couple the first metallization features to second metallization features on a second side of the glass; and a metallic layer between the metallization and the glass within each of the holes, the metallic layer comprising titanium and niobium; and a conductive seed layer between the metallic layer and the via metallization.

Example 10: The system of example 9, wherein the metal alloy layer comprises one of Ti-29Nb-11Ta-5Zr or Ti-29Nb-6Ta-5Zr.

Example 11: The apparatus of example 9, wherein the metallic layer further comprises tantalum and zirconium.

Example 12: The apparatus of any of examples 9 through 11, wherein the metallic layer comprises an elastic modulus less than 35 GPa.

Example 13: The system of any of examples 9 through 12, further comprising an electrical routing structure on the first side of the substrate, the routing structure comprising the first metallization features, and wherein the metallization within each of the plurality of holes extend from the routing structure to the second side of the substrate, and wherein the routing structure is to electrically couple at least one metallization to at least one of the plurality of IC die.

Example 14: A method comprising: receiving a workpiece comprising glass; forming holes through the glass; depositing a metallic layer upon a sidewall of the holes and over a surface of the glass and between the through holes, wherein the metallic layer comprises titanium and niobium; forming metallization within the holes and over the metallic layer; and forming conductive through vias by planarizing the metallization and the metallic layer with the surface of the glass.

Example 15: The method of example 14, wherein the metallic layer further comprises tantalum and zirconium.

Example 16: The method of any of examples 14 or 15, further comprising: building up, over the surface of the glass, an electrical routing structure coupled to the through vias; and attaching an IC die to the electrical routing structure.

Example 17: The method of any of examples 14 through 16, wherein the depositing of the metallic layer further comprises vapor depositing the metallic layer.

Example 18: The method of any of examples 14 through 17, further comprising depositing a conductive seed layer over the metallic layer using an electroless method.

Example 19: The method of any of examples 14 through 18, further comprising depositing a dry film resist layer over a surface of the glass and between the through holes.

Example 20: An apparatus, comprising: a substrate comprising glass; a plurality of holes extending through the glass; via metallization within the holes; a polymer hydrogel layer between the glass and the via metallization; and an MXene seed layer between the polymer hydrogel and the via metallization.

Example 21: The apparatus of example 20, wherein the MXene seed layer comprises titanium (Ti), and carbon (C) or nitrogen (N).

Example 22: The apparatus of any of examples 20 or 21, wherein the MXene seed layer comprises Ti3C2Tx, and Tx is a functional group comprising —OH, —F, or —O.

Example 23: The apparatus of any of examples 20 through 22, wherein the polymer hydrogel layer comprises a solvent, H2O, and an organic polymer.

Example 24: The apparatus of any of examples 20 through 23, wherein the organic polymer comprises poly (3,4-ethylenedioxythiophene) polystyrene sulfonate (PEDOT: PSS), polyvinyl alcohol, polyaniline, polyacrylamide, cellulose, chitosan, or polyacrylic acid.

Example 25: The apparatus of any of examples 20 through 24, wherein the via metallization comprises Cu.

Example 26: A system comprising: a plurality of integrated circuit (IC) die electrically coupled to first metallization features on a first side of a substrate comprising glass; a plurality of holes extending through the glass; metallization within the holes, the metallization to electrically couple the first metallization features to second metallization features on a second side of the glass; and an MXene seed layer within the holes between the glass and the metallization, wherein the MXene seed layer comprises titanium and carbon.

Example 27: The system of example 26, wherein the MXene seed layer comprises Ti₃C₂Tₓ, wherein Tₓ is a functional group comprising —OH, —F, or —O.

Example 28: The system of any of examples 26 or 27, further comprising a polymer hydrogel layer between the glass and the MXene seed layer.

Example 29: The system of any of examples 26 through 28, wherein the polymer hydrogel layer comprises a solvent, H2O, and an organic polymer.

Example 30: The system of any of examples 26 through 29, further comprising an electrical routing structure on the first side of the substrate, the routing structure comprising the first metallization features, and wherein the metallization within each of the plurality of holes extend from the routing structure to a second side of the substrate, and wherein the routing structure is to electrically couple at least one metallization to at least one of the plurality of IC die.

Example 31: A method comprising: receiving a substrate comprising glass; forming holes through the glass; depositing a polymer hydrogel layer upon a sidewall the holes and over a surface of the glass; depositing an MXene seed layer over the polymer hydrogel layer; removing the polymer hydrogel and MXene seed layer from the surface of the glass; forming metallization within the holes and over the polymer hydrogel and MXene seed layer; and forming conductive through vias by planarizing the metallization on the surface of the substrate.

Example 32: The method of example 31, further comprising: building up, over the surface of the glass, an electrical routing structure coupled to the through vias; and attaching an IC die to the electrical routing structure.

Example 33: The method of any of examples 31 or 32, wherein the depositing the polymer hydrogel comprises inkjet printing, slit coating, spin coating, spray coating, or doctor blade coating.

Example 34: The method of any of examples 31 through 33, wherein the depositing the MXene seed layer comprises vapor deposition.

Example 35: A method comprising: receiving a workpiece comprising glass; forming holes through the glass; depositing a conductive seed layer upon a sidewall of the holes and over a surface of the glass between the holes; biasing the glass to a first polarity; depositing a polymer upon the sidewall of the holes and over the surface of the glass between the holes, the polymer comprising particles charged to a second polarity opposite the first polarity; forming metallization within the holes and over the polymer; and forming conductive through vias by planarizing the metallization and the polymer with the surface of the glass.

Example 36: The method of example 35, further comprising depositing a conductive seed layer upon the sidewall of the holes and over the surface of the glass between the holes.

Example 37: The method of any of examples 35 or 36, further comprising annealing the polymer.

Example 38: The method of any of examples 35 through 37, wherein the polymer particles have an ammonium, sulfonium, or phosphonium component.

Example 39: The method of any of examples 35 through 37, wherein the polymer particles have a carboxylic acid, phosphoric, or sulfonic acid component.

Example 40: The method of any of examples 35 through 39, wherein the conductive seed layer comprises TiCu.

Example 41: The method of any of examples 35 through 40, wherein the depositing a polymer further comprises immersing the substrate in a solution comprising the polymer.

Example 42: The method of any of examples 35 through 40, further comprising: positioning a mask over a surface of the glass, the mask comprising openings extending through the mask, wherein the mask is positioned so that the openings are aligned with the holes; and biasing the mask to the second polarity.

Example 43: The method of any of examples 35 through 40, or example 42, wherein the depositing a polymer further comprises exposing the substrate to an aerosol comprising the polymer.

Example 44: The method of any of examples 35 through 42, further comprising depositing second conductive seed particles over the polymer.

Example 45: The method of any of examples 35 through 42, or example 44, further comprising: building up, over the surface of the glass, an electrical routing structure coupled to the through vias; and attaching an IC die to the electrical routing structure.

Example 46: An apparatus, comprising: a substrate comprising glass; a plurality of holes extending through the glass; via metallization within the holes; a polymer material layer within the holes between the via metallization and the glass, wherein the polymer material layer comprises a polymer material having an average surface roughness of between 10 nm and 500 nm.

Example 47: The apparatus of example 46, further comprising a conductive seed layer between the polymer material layer and the glass.

Example 48: The apparatus of any of examples 46 or 47, wherein the polymer material layer comprises: particles having an ammonium, sulfonium, or phosphonium component; or particles having a carboxylic acid, phosphoric, or sulfonic acid component.

Example 49: The apparatus of any of examples 46 or 47, wherein the polymer material comprises a first layer and a second layer over the first layer, wherein: the first layer comprises particles having one of: an ammonium, sulfonium, or phosphonium component; or a carboxylic acid, phosphoric, or sulfonic acid component; and the second layer comprises particles having the other of: the ammonium, sulfonium, or phosphonium component; or the carboxylic acid, phosphoric, or sulfonic acid component.

Example 50: The apparatus of any of examples 46 through 49, wherein the conductive seed layer comprises TiCu.

Example 51: A system comprising: a plurality of integrated circuit (IC) die electrically coupled to first metallization features on a first side of a substrate comprising glass; a plurality of holes extending through the glass; a metallization within the holes, the metallization to electrically couple the first metallization features to second metallization features on a second side of the glass; and a liner within the holes and between the metallization and the glass, wherein the liner comprises: a polymer layer; and a plurality of metallic particles between the polymer and the glass.

Example 52: The system of example 51, wherein the polymer layer comprises: nanoparticles of an ammonium group; or nanoparticles of carboxylate, phosphate, or sulfonate.

Example 53: The system of any of examples 51 or 52, wherein the polymer material layer comprises a polymer material having an average surface roughness of between 10 nm and 300 nm.

Example 54: The system of any of examples 51 through 53, further comprising an electrical routing structure on the first side of the glass, the routing structure comprising the first metallization features and an organic dielectric material, and wherein the plurality of through vias extend from the routing structure to a second side of the glass, and wherein the routing structure is to electrically couple the through vias to at least one of the plurality of IC die.

Example 55: An apparatus, comprising: a substrate comprising glass; a plurality of holes extending through the glass; a via metallization within the holes; and an organic layer and a metal layer within the holes, the organic material layer and the metal layer between the via metallization and the glass, wherein: the organic layer comprises an epoxy-based dielectric, a polyimide, or a parylene; and the metal layer comprising Al, Sn, Sc, or In.

Example 56: The apparatus of example 55, wherein the organic layer is between the metal layer and a sidewall of the hole, or the metal layer is between the organic layer and the sidewall of the hole.

Example 57: The apparatus of any of examples 55 or 56, wherein the metal layer is a first metal layer, further comprising: a second metal layer, wherein the organic layer is between the first metal layer and the second metal layer.

Example 58: The apparatus of example 57, wherein the second metal layer comprises Al, Sn, Sc, or In, or Ti.

Example 59: The apparatus of any of examples 55 through 56, wherein the organic layer comprises an epoxy-based dielectric, a polyimide, or a parylene.

Example 60: The apparatus of any of examples 55 through 56, or example 59, wherein the metal layer comprises titanium and niobium.

Example 61: The apparatus of any of examples 55 through 56, or examples 59 through 60, wherein the organic layer comprises an epoxy-based dielectric, a polyimide, or a parylene.

Example 62: The apparatus of any of examples 55 through 56, or examples 59 through 61, wherein: the organic layer having comprises a thickness between 1 and 10 μm; and the metal layer comprises a thickness between 0.1 and 2 μm.

Example 63: The apparatus of any of examples 55 through 56, or examples 59 through 62, wherein the via metallization comprises Cu.

Example 64: A system comprising: a plurality of integrated circuit (IC) die electrically coupled to first metallization features on a first side of a substrate, the substrate comprising glass and a plurality of holes extending through the glass; a metallization within the holes, the metallization to electrically couple the first metallization features to second metallization features on a second side of the glass; and an organic layer and a metal layer within the holes, the organic material layer and the metal layer between the via metallization and the glass, wherein: the organic layer comprises an epoxy-based dielectric, a polyimide, or a parylene; and the metal layer comprising titanium and niobium.

Example 65: The system of example 64, wherein the metal layer comprises Al, Sn, Sc, or In.

Example 66: The apparatus of any of examples 64 or 65, wherein the metal layer is a first metal layer, further comprising: a second metal layer, wherein the organic layer is between the first metal layer and the second metal layer.

Example 67: The apparatus of example 66, wherein the second metal layer comprises Al, Sn, Sc, or In, or Ti.

Example 68: The system of any of examples 64 or 65, further comprising an electrical routing structure on the first side of the substrate, the routing structure comprising the first metallization features, and wherein the metallization within the plurality of holes extends from the routing structure to a second side of the substrate, and wherein the routing structure is to electrically couple at least one first metal feature to at least one of the plurality of IC die.

Example 69: A method comprising: receiving a workpiece comprising glass; forming one or more holes through the glass; forming an organic layer and a metal layer within the holes, the organic material layer and the metal layer between the via metallization and the glass, wherein: the organic layer comprises an epoxy-based dielectric, a polyimide, or a parylene; and the metal layer comprising Al, Sn, Sc, or In; and forming metallization within the holes.

Example 70: The method of example 69, wherein the forming the organic layer comprises depositing an organic material using a vapor deposition, slit coating, spray coating, or vacuum lamination process.

Example 71: The method of any of examples 69 or 70, wherein the organic layer comprises an epoxy-based dielectric, a polyimide, or a parylene.

Example 72: The method of any of examples 69 through 71, wherein the forming the metal layer comprises depositing a metal using a sputter or atomic layer deposition process.

Example 73: The method of any of examples 69 through 72, wherein the metal layer comprises titanium and niobium.

Example 74: The method of any of examples 69 through 73, wherein the organic layer is between the metal layer and the sidewall of the hole, or the metal layer is between the organic material layer and the sidewall of the hole.

Example 75: The method of any of examples 69 through 74, further comprising: building up, over the surface of the glass, an electrical routing structure coupled to the through vias; and attaching an IC die to the electrical routing structure.

Example 76: An apparatus, comprising: a substrate comprising glass; a plurality of holes extending through the glass; a via metallization within the holes; and a liner within each of the holes, the liner between the via metallization and the glass, wherein the liner comprises: a first metal layer; an organic material layer; and a second metal layer, wherein the organic material layer is between the first metal layer and the second metal layer.

Example 77: The apparatus of example 76, wherein the first metal layer comprises one of Al, Sn, Sc, In, or Ti, and the second metal layer comprises one of Al, Sn, Sc, In, or Ti.

Example 78: The apparatus of any of examples 76 or 77, wherein the first metal layer and the second metal layer each comprise an alloy, wherein each alloy comprises at least two of Al, Sn, Sc, In, or Ti.

Example 79: The apparatus of any of examples 76 through 78, wherein the organic material layer comprises an epoxy-based dielectric, a polyimide, or a parylene, or GY18E.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a substrate comprising glass and a plurality of holes extending through the glass;
a via metallization within each of the holes; and
a metallic layer within the holes, wherein:
the metallic layer is between the via metallization and the glass; and
the metallic layer comprises titanium and niobium.

2. The apparatus of claim 1, wherein the metallic layer further comprises tantalum and zirconium.

3. The apparatus of claim 1, wherein the metallic layer comprises an elastic modulus less than 40 GPa.

4. The apparatus of claim 1, further comprising a conductive seed layer between the metallic layer and the via metallization.

5. An apparatus, comprising:
a substrate comprising glass;
a plurality of holes extending through the glass;
via metallization within the holes;
a polymer hydrogel layer between the glass and the via metallization; and
an MXene seed layer between the polymer hydrogel layer and the via metallization.

6. The apparatus of claim 5, wherein the MXene seed layer comprises Ti₃C₂Tₓ, and Tₓ is a functional group comprising —OH, —F, or —O.

7. The apparatus of claim 5, wherein the polymer hydrogel layer comprises a solvent, H₂O, and an organic polymer.

8. The apparatus of claim 7, wherein the organic polymer comprises poly (3,4-ethylenedioxythiophene) polystyrene sulfonate (PEDOT: PSS), polyvinyl alcohol, polyaniline, polyacrylamide, cellulose, chitosan, or polyacrylic acid.

9. An apparatus, comprising:
a substrate comprising glass;
a plurality of holes extending through the glass;
via metallization within the holes; and
a polymer layer within the holes between the via metallization and the glass, wherein
the polymer layer comprises a polymer material having an average surface roughness of between 10 nm and 500 nm.

10. The apparatus of claim 9, further comprising a metal seed layer between the polymer layer and the glass.

11. The apparatus of claim 9, wherein the polymer layer comprises:
particles having an ammonium component; or
particles having a carboxylate, phosphate, or sulfonate component.

12. The apparatus of claim 9, wherein the polymer layer comprises a first layer and a second layer over the first layer, wherein:
the first layer comprises particles having one of:
an ammonium component; or
a carboxylate, phosphate, or sulfonate component; and
the second layer comprises particles having the other of:
the ammonium component; or
the carboxylate, phosphate, or sulfonate component.

13. An apparatus, comprising:
a substrate comprising glass;
a plurality of holes extending through the glass;
a via metallization within the holes; and
an organic layer and a metal layer within the holes, the organic layer and the metal layer between the via metallization and the glass, wherein:
the organic layer comprises an epoxy-based dielectric, a polyimide, or a parylene; and
the metal layer comprising Al, Sn, Sc, or In.

14. The apparatus of claim 13, wherein the organic layer is between the metal layer and sidewalls of the holes, or the metal layer is between the organic layer and the sidewalls of the holes.

15. The apparatus of claim 13, wherein the metal layer is a first metal layer, further comprising:
a second metal layer, wherein the organic material layer is between the first metal layer and the second metal layer.

16. The apparatus of claim 15, wherein the second metal layer comprises Al, Sn, Sc, or In, or Ti.

17. The apparatus of claim 13, wherein the organic material layer comprises an epoxy-based dielectric, a polyimide, or a parylene.

18. The apparatus of claim 15, wherein the metal layer comprises titanium and niobium.

19. A method comprising:
receiving a workpiece comprising glass;
forming holes through the glass;
depositing a conductive seed layer upon a sidewall of the holes and over a surface of the glass between the holes;
biasing the glass to a first polarity;
depositing a polymer upon the sidewall of the holes and over the surface of the glass between the holes, the polymer comprising nanoparticles charged to a second polarity opposite the first polarity;
forming metallization within the holes and over the polymer; and
forming conductive through vias by planarizing the metallization and the polymer with the surface of the glass.

20. The method of claim 19, further comprising:
positioning a mask over a surface of the glass, the mask comprising openings extending through the mask, wherein the mask is positioned so that the openings are aligned with the holes; and
biasing the mask to the second polarity.

21. A system comprising:
a plurality of integrated circuit (IC) die electrically coupled to first metallization features on a first side of a substrate, the substrate comprising glass and a plurality of holes extending through the glass;
a metallization within the holes, the metallization to electrically couple the first metallization features to second metallization features on a second side of the glass; and
a liner within the holes, the liner between the metallization and the glass, wherein the liner comprises:
an organic material layer comprising an epoxy-based dielectric, a polyimide, or a parylene; and
a metal layer comprising a beta-titanium alloy layer having an elastic modulus less than 40 GPa.

22. The system of claim 21, wherein the metal layer is a first metal layer, further comprising a second metal layer comprising Al, Sn, Sc, or In, wherein the organic material layer is between the first metal layer and the second metal layer.
